(19) United States
(12) Patent Application Publication
(10) Pub. No.: US 2012/0038428 A1
(43) Pub. Date: Feb. 16, 2012

(54) Oscillators and method of operating the same

(75) Inventors: Sung-chul Lee, Osan-si (KR); Ung-hwan Pi, Seoul (KR); Kee-won Kim, Suwon-si (KR); Kwang-seok Kim, Seongnam-si (KR); Ho-jung Kim, Suwon-si (KR); Hyun-sik Choi, Hwaseong-si (KR)

(73) Assignee: Samsung Electronics Co., Ltd., Suwon-si (JP)

(21) Appl. No.: 12/929,388

(22) Filed: Jan. 20, 2011

(30) Foreign Application Priority Data
Aug. 13, 2010 (KR) 10-2010-0078489

(51) Int. Cl. H03B 5/02

(52) U.S. Cl. 331/108 R

(57) ABSTRACT

Oscillators and a method of operating the same are provided, the oscillators include at least one oscillation device including a first magnetic layer having a magnetization direction that is variable, a second magnetic layer having a pinned magnetization direction, and a non-magnetic layer disposed between the first magnetic layer and the second magnetic layer. The oscillation device is configured to generate a signal having a set frequency. The oscillators further include a driving transistor having a drain connected to the at least one oscillation device, and a gate to which a control signal for controlling driving of the oscillation device is applied.

### CROSS-REFERENCE TO RELATED APPLICATIONS

This application claims the benefit of priority under 35 U.S.C. §119 from Korean Patent Application No. 10-2010-0078489, filed on Aug. 13, 2010, in the Korean Intellectual Property Office, the disclosures of which are incorporated herein in their entirety by reference.

### BACKGROUND

1. Field

Example embodiments relate to oscillators, and more particularly, to oscillators having variable frequency and a method of operating the oscillators.

2. Description of the Related Art

Oscillators generate signals having a constant frequency and may be used in wireless communication systems (e.g., a mobile communication terminal, a satellite and radar communication device, a wireless network device, a communication device for a vehicle, etc.), or analog sound synthesizers. Oscillators need to be manufactured in consideration of various factors such as a quality factor, output power, phase noise, etc.

### SUMMARY

Example embodiments relate to oscillators, and more particularly, to oscillators having variable frequency and a method of operating the oscillators.

Provided is oscillators capable of providing high output power and a method of operating the oscillators.

Additional aspects will be set forth in part in the description which follows and, in part, will be apparent from the description, or may be learned by practice of the presented embodiments.

According to example embodiments, an oscillator includes at least one oscillation device including a first magnetic layer, a second magnetic layer having a pinned magnetization direction, and a non-magnetic layer disposed between the first magnetic layer and the second magnetic layer. The first magnetic layer has a magnetization direction that is variable according to at least one selected from the group consisting of an applied current, an applied voltage and an applied magnetic field. The at least one oscillation device is configured to generate a signal having a set frequency. The oscillator further includes a driving transistor having a drain connected to the at least one oscillation device, and a gate to which a control signal for controlling driving of the oscillation device is applied.

A magnetic moment of the first magnetic layer may precess according to at least one selected from the group consisting of an applied current, an applied voltage, and an applied magnetic field. Thus, a resistance of the oscillation device is periodically changed, and thereby the oscillation device generates the signal having the set frequency.

The drain may be connected to an output node of the oscillation device, and the output node is the first magnetic layer or the second magnetic layer.

Even when a resistance of the oscillation device is periodically changed according to time, a current flowing to the output node may be hardly changed (or fixed), and a voltage of the output node may oscillate at a set amplitude.

The amplitude of the voltage of the output node may be greater than that of a voltage of the output node when the output node is connected to a source of the driving transistor.

The second magnetic layer may include a first pinned layer disposed adjacent to the non-magnetic layer and having a first magnetization direction, a separation layer disposed adjacent to the first pinned layer, and a second pinned layer disposed adjacent to the separation layer and having a second magnetization direction opposite to the first magnetization direction.

The second magnetic layer may include a pinned layer adjacent to the non-magnetic layer, and an anti-ferromagnetic layer adjacent to the pinned layer, wherein a magnetization direction of the pinned layer is pinned in a direction corresponding to a magnetic moment of an uppermost portion of the anti-ferromagnetic layer.

The oscillator may include at least two oscillation devices connected to each other in series. The oscillator may include at least two oscillation devices connected to each other in parallel. The oscillator may include at least three oscillation devices connected to one another in series and in parallel.

The first magnetic layer may be disposed over the non-magnetic layer and the second magnetic layer. The second magnetic layer may be disposed over the non-magnetic layer and the first magnetic layer.

When a magnetic field having a direction opposite to the pinned magnetization direction of the second magnetic layer is applied to the first magnetic layer, a current is applied in a direction from the first magnetic layer to the second magnetic layer. When a magnetic field having a direction that is the same as the pinned magnetization direction of the second magnetic layer is applied to the first magnetic layer, a current is applied in a direction from the second magnetic layer to the first magnetic layer.

The oscillator may further include an amplifier connected to the output node and configured to amplify a voltage of the output node.

The non-magnetic layer may be an insulating layer, and the oscillation device has a tunneling magnetoresistance (TMR) structure. The non-magnetic layer may be a conductive layer, and the oscillation device has a giant magnetoresistance (GMR) structure.

According to example embodiments, a method of operating an oscillator including an oscillation device including a first magnetic layer, a second magnetic layer and a non-magnetic layer disposed between the first magnetic layer and the second magnetic layer, and a driving transistor having a drain connected to the oscillation device, is provided. The method includes applying a current having a set direction to the oscillation device based on a direction of a magnetic field applied to the first magnetic layer, and generating a signal having a set frequency by using a precession of a magnetic moment of the first magnetic layer that occurs based on to the direction of the magnetic field and the set direction of the current.

The driving transistor may further include a gate to which a control signal for controlling driving of the oscillation device is applied. The method of operating the oscillator may further include outputting the signal having the set frequency when the control signal is activated. The method may further include amplifying the signal having the set frequency to a set level.

### BRIEF DESCRIPTION OF THE DRAWINGS

These and/or other aspects will become apparent and more readily appreciated from the following description of the embodiments, taken in conjunction with the accompanying drawings of which:

FIG. 1 is a circuit diagram illustrating an oscillator according to example embodiments;

FIG. 2 illustrates another example of an oscillation device included in the oscillator of FIG. 1;

FIG. 3 is a graph showing a relationship between drain voltage and current with respect to a driving transistor included in the oscillator of FIG. 1;

FIG. 4 is a graph showing a relationship between time and drain voltage with respect to the driving transistor included in the oscillator of FIG. 1;

FIG. 5 is a circuit diagram illustrating an oscillator according to a comparative example with respect to the oscillator of FIG. 1;

FIG. 6 is a graph showing a relationship between source voltage and current with respect to a driving transistor included in the oscillator of FIG. 5;

FIG. 7 is a graph showing a relationship between time and source voltage with respect to the driving transistor included in the oscillator of FIG. 5;

FIG. 8 is a circuit diagram illustrating the oscillator of FIG. 1 when an external magnetic field is applied in a first direction;

FIG. 9 is a circuit diagram illustrating the oscillator of FIG. 1 when an external magnetic field is applied in a second direction;

FIG. 10 is a circuit diagram illustrating an oscillator according to example embodiments;

FIG. 11 is a graph showing a relationship between drain voltage and current with respect to a driving transistor included in the oscillator of FIG. 10;

FIG. 12 is a graph showing a relationship between time and drain voltage with respect to the driving transistor included in the oscillator of FIG. 10;

FIG. 13 is a circuit diagram illustrating an oscillator according to a comparative example with respect to the oscillator of FIG. 10;

FIG. 14 is a graph showing a relationship between source voltage and current with respect to a driving transistor included in the oscillator of FIG. 13;

FIG. 15 is a graph showing a relationship between time and source voltage with respect to the driving transistor included in the oscillator of FIG. 13;

FIG. 16 is a circuit diagram illustrating the oscillator of FIG. 10 when an external magnetic field is applied in a first direction;

FIG. 17 is a circuit diagram illustrating the oscillator of FIG. 10 when an external magnetic field is applied in a second direction;

FIG. 18 is a circuit diagram illustrating an oscillator according to example embodiments;

FIG. 19 is a circuit diagram illustrating the oscillator of FIG. 18 when an external magnetic field is applied in a first direction;

FIG. 20 is a circuit diagram illustrating the oscillator of FIG. 18 when an external magnetic field is applied in a second direction;

FIG. 21 is a circuit diagram illustrating an oscillator according to example embodiments;

FIG. 22 is a circuit diagram illustrating the oscillator of FIG. 21 when an external magnetic field is applied in a first direction;

FIG. 23 is a circuit diagram illustrating the oscillator of FIG. 21 when an external magnetic field is applied in a second direction;

FIG. 24 is a circuit diagram illustrating an oscillator including a plurality of oscillation devices connected to each other in series according to example embodiments;

FIG. 25 is a circuit diagram illustrating an oscillator including a plurality of oscillation devices connected to each other in parallel according to example embodiments;

FIG. 26 is a circuit diagram illustrating an oscillator including a plurality of oscillation devices connected to one another in series and in parallel according to example embodiments; and

FIG. 27 is a flowchart illustrating a method of operating an oscillator according to example embodiments.

### DETAILED DESCRIPTION

Various example embodiments will now be described more fully with reference to the accompanying drawings in which some example embodiments are shown. However, specific structural and functional details disclosed herein are merely representative for purposes of describing example embodiments. Thus, the invention may be embodied in many alternate forms and should not be construed as limited to only example embodiments set forth herein. Therefore, it should be understood that there is no intent to limit example embodiments to the particular forms disclosed, but on the contrary, example embodiments are to cover all modifications, equivalents, and alternatives falling within the scope of the invention.

In the drawings, the thicknesses of layers and regions may be exaggerated for clarity, and like numbers refer to like elements throughout the description of the figures.

Although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of example embodiments. As used herein, the term “and/or” includes any and all combinations of one or more of the associated listed items.

It will be understood that, if an element is referred to as being “connected” or “coupled” to another element, it can be directly connected, or coupled, to the other element or intervening elements may be present. In contrast, if an element is referred to as being “directly connected” or “directly coupled” to another element, there are no intervening elements present. Other words used to describe the relationship between elements should be interpreted in a like fashion (e.g., “between” versus “directly between,” “adjacent” versus “directly adjacent,” etc.).

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises,” “comprising,” “includes” and/or “including,” if used herein, specify the presence of stated features, integers, steps, operations, elements and/or components, but do not preclude the presence or addition of one or more other features, integers, steps, operations, elements, components and/or groups thereof.

Spatially relative terms (e.g., “beneath,” “below,” “lower,” “above,” “upper” and the like) may be used herein for ease of description to describe one element or a relationship between a feature and another element or feature as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, for example, the term “below” can encompass both an orientation that is above, as well as, below. The device may be otherwise oriented (rotated 90 degrees or viewed or referenced at other orientations) and the spatially relative descriptors used herein should be interpreted accordingly.

Example embodiments are described herein with reference to cross-sectional illustrations that are schematic illustrations of idealized embodiments (and intermediate structures). As such, variations from the shapes of the illustrations as a result, for example, of manufacturing techniques and/or tolerances, may be expected. Thus, example embodiments should not be construed as limited to the particular shapes of regions illustrated herein but may include deviations in shapes that result, for example, from manufacturing. For example, an implanted region illustrated as a rectangle may have rounded or curved features and/or a gradient (e.g., of implant concentration) at its edges rather than an abrupt change from an implanted region to a non-implanted region. Likewise, a buried region formed by implantation may result in some implantation in the region between the buried region and the surface through which the implantation may take place. Thus, the regions illustrated in the figures are schematic in nature and their shapes do not necessarily illustrate the actual shape of a region of a device and do not limit the scope.

It should also be noted that in some alternative implementations, the functions/acts noted may occur out of the order noted in the figures. For example, two figures shown in succession may in fact be executed substantially concurrently or may sometimes be executed in the reverse order, depending upon the functionality/acts involved.

Unless otherwise defined, all terms (including technical and scientific terms) used herein have the same meaning as commonly understood by one of ordinary skill in the art to which example embodiments belong. It will be further understood that, terms, such as those defined in commonly used dictionaries, should be interpreted as having a meaning that is consistent with their meaning in the context of the relevant art and will not be interpreted in an idealized or overly formal sense unless expressly so defined herein.

In order to more specifically describe example embodiments, various aspects will be described in detail with reference to the attached drawings. However, the present invention is not limited to example embodiments described.

Example embodiments relate to oscillators, and more particularly, to oscillators having variable frequency and a method of operating the oscillators.

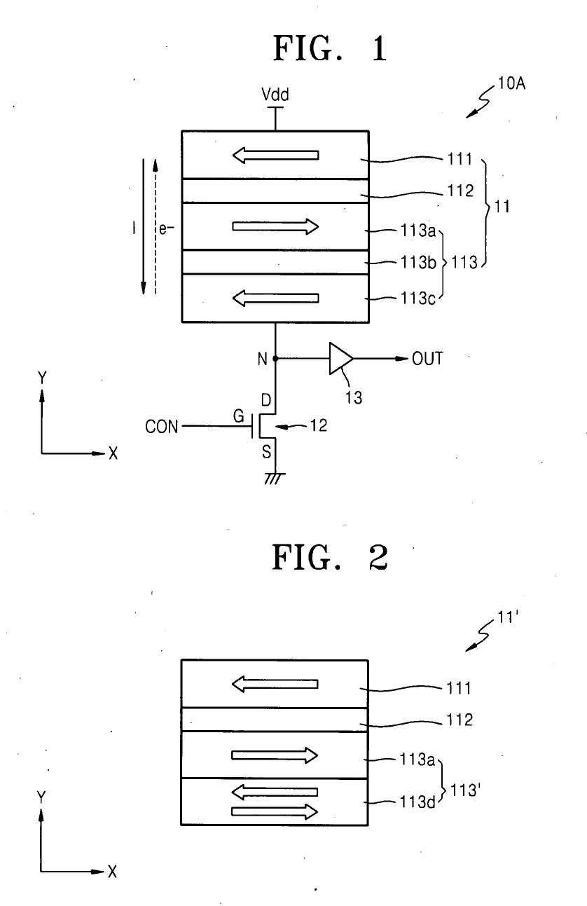

FIG. 1 is a circuit diagram illustrating an oscillator according to example embodiments.

Referring to FIG. 1, an oscillator 10A may include an oscillation device 11 and a driving transistor 12. The oscillation device 11 may be configured in the form of a spin valve including a first magnetic layer 111, a non-magnetic layer 112 and a second magnetic layer 113. The first magnetic layer 111 of the oscillation device 11 may be disposed above the second magnetic layer 113, and thus the oscillation device 11 may have a structure in which the second magnetic layer 113, the non-magnetic layer 112, and the first magnetic layer 111 are sequentially stacked. The oscillator 10A may further include an amplifier 13.

Although not shown in FIG. 1, electrode layers may be disposed on the first magnetic layer 111 and under the second magnetic layer 113. However, when an electric resistance of the first or second magnetic layer 111 or 113 is sufficiently low, the first or second magnetic layer 111 or 113 itself may be used as an electrode. Thus, it may not be necessary to dispose an additional electrode layer on the first magnetic layer 111 or under the second magnetic layer 113.

The first magnetic layer 111 may be a free layer having a magnetization direction that varies according to at least one selected from the group consisting of an applied current, an applied voltage and an applied magnetic field. In example embodiments, the oscillation device 11 includes only one first magnetic layer 111, but example embodiments are not limited thereto. Alternatively, the oscillation device 11 may include at least two first magnetic layers 111. At this time, a separation layer (e.g., an insulating layer or a conductive layer) may be disposed between the two first magnetic layers 111.

The first magnetic layer 111 may have perpendicular magnetic anisotropy or in-plane magnetic anisotropy. When the first magnetic layer 111 has perpendicular magnetic anisotropy, the first magnetic layer 111 may be an alloy layer formed of an alloy including cobalt (Co) (e.g., CoPt or CoCrPt), or may be a multi-layer. The multi-layer may, for example, include a layer including at least one selected from the group consisting of Co and an alloy including Co, and a layer including at least one selected from the group consisting of platinum (Pt), nickel (Ni), and palladium (Pd), are alternately stacked. When the first magnetic layer 111 has in-plane magnetic anisotropy, the first magnetic layer 111 may be a material layer including at least one selected from the group consisting of Co, Ni, and iron (Fe) (e.g., CoFeB or NiFe). However, the configuration of the first magnetic layer 111 is not limited to the above-described examples. In general, a material of a free layer used in a magnetic device may be used as a material of the first magnetic layer 111.

The non-magnetic layer 112 may be disposed between the first magnetic layer 111 and the second magnetic layer 113, and may be configured as a conductive layer or an insulating layer. When the non-magnetic layer 112 is configured as a conductive layer, the non-magnetic layer 112 may be a layer including at least one selected from the group consisting of copper (Cu), aluminum (Al), gold (Au), silver (Ag) and a compound thereof. If the non-magnetic layer 112 is a conductive layer, the oscillation device 11 may have a giant magnetoresistance (GMR) structure. When the non-magnetic layer 112 is configured as an insulating layer, the non-magnetic layer 112 may be a layer including an oxide (e.g., MgO or AlOₓ). At this time, the oscillation device 11 may have a tunneling magnetoresistance (TMR) structure.

The second magnetic layer 113 may be a pinned layer having a pinned magnetization direction. In example embodiments, the second magnetic layer 113 may have a structure in which a first pinned layer 113a, a separation layer 113b and a second pinned layer 113c are stacked. At this time, exchange coupling may occur between the first pinned layer 113a and the second pinned layer 113c. The first and second pinned layers 113a and 113c may respectively have magnetization directions pinned in opposite directions. In example embodiments, the second pinned layer 113c may have a magnetization direction pinned in a negative x-axis direction, and the first pinned layer 113a may have a magnetization direction pinned in a positive x-axis direction.

For example, the first and second pinned layers 113a and 113c may be formed of a ferromagnetic material including at least one selected from the group consisting of Co, Fe, and Ni. The separation layer 113b may be formed of a conductive material (e.g., ruthenium (Ru) or chrome (Cr)). In example embodiments, the first and second pinned layers 113a and 113c may include Co, and the separation layer 113b may include Ru. Thus, the second magnetic layer 113 may have a stacked structure of Co/Ru/Co.

The driving transistor 12 may be an NMOS transistor having a drain D connected to the oscillation device 11, a gate G to which a control signal CON for controlling driving of the oscillation device 11 is applied, and a source S connected to a ground terminal. When the control signal CON is activated, the driving transistor 12 may be turned on, and an output voltage of the oscillation device 11 may be provided to the amplifier 13. In example embodiments, the drain D of the driving transistor 12 may be connected to an output node N of the oscillation device 11 (i.e., to the second magnetic layer 113).

The amplifier 13 may be connected to the output node N of the oscillation device 11 so as to amplify the output voltage of the oscillation device 11 to a set (or threshold) level to provide an output voltage OUT.

Hereinafter, operations of the oscillation device 11 will be described in detail.

In example embodiments, the oscillation device 11 may be connected between a power voltage Vdd terminal and the output node N. In detail, the first magnetic layer 111 may be connected to the power voltage Vdd terminal to apply a power voltage Vdd to the first magnetic layer 111. The second pinned layer 113c of the second magnetic layer 113 may be connected to the output node N. Thus, a current I may be applied in a negative y-axis direction (i.e., in a direction from the first magnetic layer 111 to the second magnetic layer 113). Electrons e− may move in a positive y-axis direction (i.e., in a direction from the second magnetic layer 113 to the first magnetic layer 111).

The electrons e− having passed through the second magnetic layer 113 may have a spin direction that is the same as that of the first pinned layer 113a, (i.e., a spin direction in the positive x-axis direction), and thus a spin torque in the positive x-axis direction may be applied to the first magnetic layer 111. A magnetic moment of the first magnetic layer 111 may be perturbed due to the spin torque. When an additional external magnetic field is not applied to the oscillation device 11, a stray field in the negative x-axis direction may be applied to the first magnetic layer 111 due to the first pinned layer 113a. Thus, a restoring force may be applied to the magnetic moment of the first magnetic layer 111 due to the stray field.

As such, the spin torque in the positive x-axis direction and the stray field in the negative x-axis direction may be applied to the first magnetic layer 111. A force due to the spin torque, which perturbs the magnetic moment of the first magnetic layer 111, and a force due to the stray field, which restores the magnetic moment of the first magnetic layer 111, are balanced. Thus, an axis of the magnetic moment of the first magnetic layer 111 may rotate while tracing a specific track. At this time, an axis direction of the magnetic moment may be regarded as a magnetization direction, and a precession of the magnetic moment may be regarded as a rotation of the magnetization direction. An angle formed by magnetization directions of the first magnetic layer 111 and the second magnetic layer 113 may be periodically changed according to the precession of the magnetic moment. Thus, an electric resistance of the oscillation device 11 may be periodically changed. As a result, the oscillation device 11 may generate a signal having a set frequency.

The oscillation device 11 may be manufactured substantially small compared to conventional LC oscillators and conventional film bulk acoustic resonator (FBAR) oscillators. The oscillation device 11 may have a high quality factor. However, the oscillation device 11 may have low output power due to its small size.

According to example embodiments, the oscillation device 11 is connected to the drain D and not to the source S of the driving transistor 12. A current through the driving transistor 12 may be controlled according to a difference between a source voltage and a gate voltage applied to the driving transistor 12. Accordingly, although the resistance of the oscillation device 11 is periodically changed according to time, a current through the driving transistor 12 may be maintained at a set level (or fixed current), and a voltage of the drain D (i.e., a voltage of the output node N) may be considerably changed. Output power of the oscillator device 11 is proportional to a square of the voltage of the output node N, thereby providing high output power.

FIG. 2 illustrates another example of an oscillation device that may be included in the oscillator of FIG. 1.

Referring to FIG. 2, an oscillation device 11′ may include a first magnetic layer 111, a non-magnetic layer 112, and a second magnetic layer 113′. The second magnetic layer 113′ may include a ferromagnetic layer 113a and an anti-ferromagnetic layer 113d. In this regard, the ferromagnetic layer 113a may be configured substantially in the same way as the first magnetic layer 113a of FIG. 1. The anti-ferromagnetic layer 113d may include a manganese-based material (e.g., InMn or FeMn). However, the configuration of the anti-ferromagnetic layer 113d is not limited thereto. Thus, any material having an anti-ferromagnetic characteristic may be used as a material of the anti-ferromagnetic layer 113d.

In the anti-ferromagnetic layer 113d, magnetic moments of atoms are regularly arranged in forward and reverse directions. A magnetization direction of the ferromagnetic layer 113a may be pinned in a direction corresponding to a magnetic moment of an uppermost portion of the anti-ferromagnetism layer 113d. In the example embodiments, the magnetic moment of the uppermost portion of the anti-ferromagnetism layer 113d is in the negative x-axis direction, and a magnetization direction of the ferromagnetic layer 113a may be pinned in the positive x-axis direction.

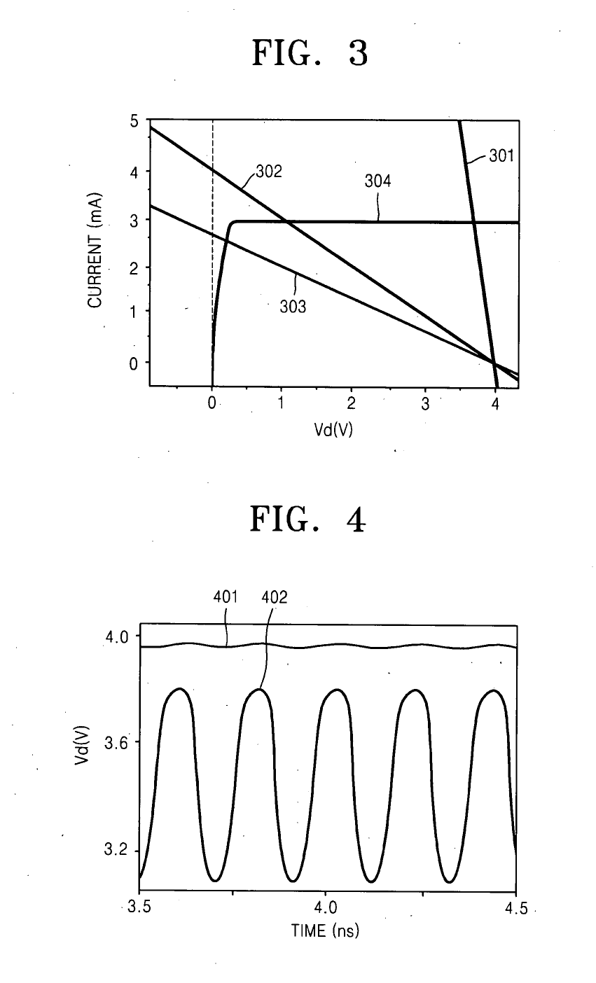

FIG. 3 is a graph showing a relationship between drain voltage and current with respect to the driving transistor included in the oscillator of FIG. 1.

Referring to FIG. 3, an X-axis of the graph represents a drain voltage Vd of the driving transistor 12, and the drain voltage Vd is represented in units of volts (V). Meanwhile, a Y-axis of the graph represents current, and the current is represented in units of amperes (mA). For example, the power voltage Vdd may be 4V, and a case where the power voltage Vdd is 4V will be described below in detail.

Reference numeral 301 denotes a current (=(4−Vd)/100) flowing to the oscillation device 11 when the electric resistance of the oscillation device 11 is 100Ω. Reference numeral 302 denotes a current (=(4−Vd)/1000) flowing to the oscillation device 11 when the electric resistance of the oscillation device 11 is 1000Ω. Reference numeral 303 denotes a current (=(4−Vd)/1500) flowing to the oscillation device 11 when the electric resistance of the oscillation device 11 is 1500Ω. Reference numeral 304 denotes a current flowing to the drain D of the driving transistor 12 when a gate voltage Vg of the driving transistor 12 is 1 V.

According to a portion of the current 304 between the current 301 and the current 302, when the electric resistance of the oscillation device 11 is changed from 100Ω to 1000Ω, a current flowing to the drain D of the driving transistor 12 is maintained constant at about 3 mA, and the drain voltage Vd is changed from about 4V to about 1V According to a portion of the current 304 between the current 302 and the current 303, when the electric resistance of the oscillation device 11 is changed from 1000Ω to 1500Ω, a current flowing to the drain D of the driving transistor 12 is maintained constant at about 3 mA and then is decreased to about 2.5 mA when the drain voltage Vd becomes close to 0 V, and the drain voltage Vd is changed from about 1 V to about 0 V.

FIG. 4 is a graph showing a relationship between time and drain voltage with respect to the driving transistor included in the oscillator of FIG. 1.

Referring to FIG. 4, an X-axis of the graph represents time in units of nanoseconds (ns). Meanwhile, a Y-axis of the graph represents the drain voltage Vd of the driving transistor 12, and the drain voltage Vd is represented in units of volts (V). For example, the power voltage Vdd may be 4 V, and a case where the power voltage Vdd is 4 V will be described below in detail.

Reference numeral 401 denotes the drain voltage Vd when the gate voltage Vg of the driving transistor 12 is 2 V. Reference numeral 402 denotes the drain voltage Vd when the gate voltage Vg of the driving transistor 12 is 1 V. Therefore, reference numeral 402 corresponds to reference numeral 304 in the graph of FIG. 3. According to reference numeral 402, because the drain voltage Vd is periodically changed from about 3.1 V to about 3.8 V according to time, the drain voltage Vd varies by about 700 mV.

According to example embodiments, because the oscillation device 11 is connected to the drain D of the driving transistor 12, although the resistance of the oscillation device 11 is periodically changed according to time, the gate voltage Vg and a source voltage of the driving transistor 12 are not changed. Accordingly, a current flowing to the driving transistor 12 (i.e., a current flowing to the output node N) may be maintained at a constant level, and the drain voltage Vd of the driving transistor 12 (i.e., the voltage of the output node N) may be periodically changed by about several hundreds of mV according to variation in the resistance of the oscillation device 11. Because the output power of the oscillation device 11 is proportional to a square of the voltage of the output node N, the output power of the oscillation device 11 may be substantially greater when the voltage of the output node N varies greatly.

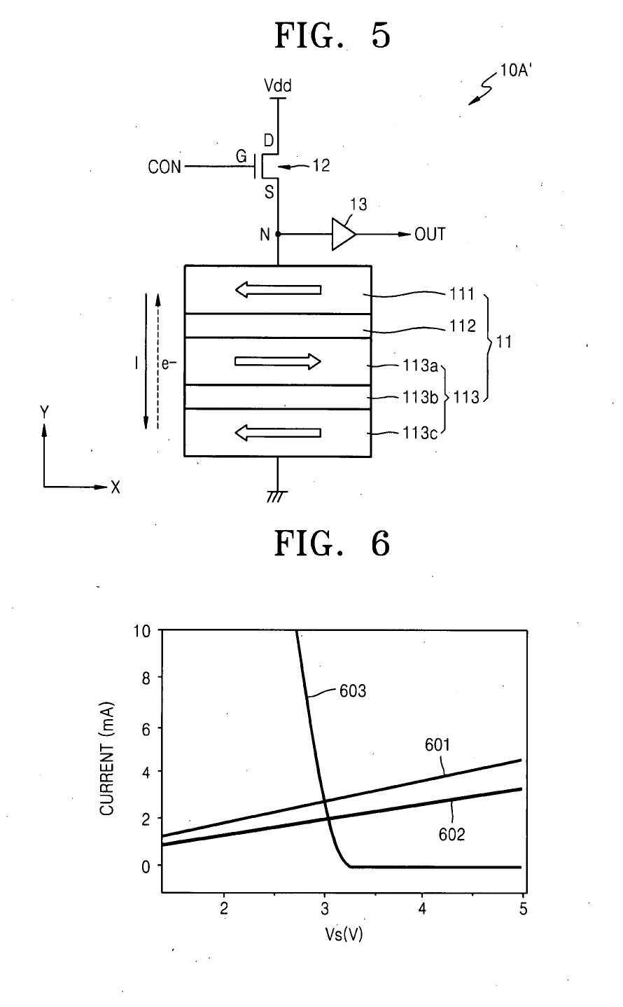

FIG. 5 is a circuit diagram illustrating an oscillator according to a comparative example with respect to the oscillator of FIG. 1.

Referring to FIG. 5, an oscillator 10A′ may include an oscillation device 11, a driving transistor 12 and an amplifier 13. The oscillation device 11, the driving transistor 12 and the amplifier 13 included in the oscillator 10A′ according to example embodiments may be configured in a similar way as the oscillation device 11, the driving transistor 12 and the amplifier 13 included in the oscillator 10A of FIG. 1. The oscillation device 11 included in the oscillator 10A of FIG. 1 is connected to the drain D of the driving transistor 12, while the oscillator 10A′ is connected to the source S of the driving transistor 12.

FIG. 6 is a graph showing a relationship between source voltage and current with respect to the driving transistor included in the oscillator of FIG. 5.

Referring to FIG. 6, an X-axis of the graph represents a source voltage Vs of the driving transistor 12, and the source voltage Vs is represented in units of volts (V). Meanwhile, a Y-axis of the graph represents current, and the current is represented in units of amperes (mA). For example, the power voltage Vdd may be 4 V, and a case where the power voltage Vdd is 4 V will be described below in detail.

Reference numeral 601 denotes a current (=Vs/1000) flowing to the oscillation device 11 when the electric resistance of the oscillation device 11 is 1000Ω. Reference numeral 602 denotes a current (=Vs/1500) flowing to the oscillation device 11 when the electric resistance of the oscillation device 11 is 1500Ω. Reference numeral 603 denotes a current flowing to the drain D of the driving transistor 12 when the gate voltage Vg of the driving transistor 12 is 4 V.

According to a portion of reference numeral 603 between reference numeral 601 and reference numeral 602, when the electric resistance of the oscillation device 11 is changed from 1000Ω to 1500Ω, the source voltage Vs is increased, and a current flowing to the drain D of the driving transistor 12 is decreased.

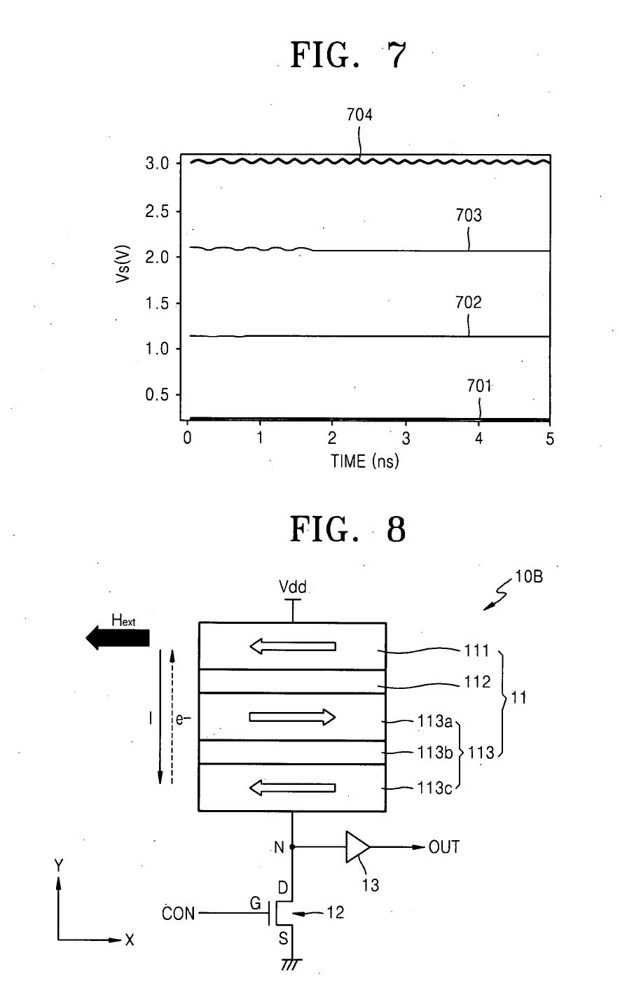

FIG. 7 is a graph showing a relationship between time and source voltage with respect to the driving transistor included in the oscillator of FIG. 5.

Referring to FIG. 7, an X-axis of the graph represents time in units of seconds (ns). Meanwhile, a Y-axis of the graph represents the source voltage Vs of the driving transistor 12, and the source voltage Vs is represented in units of volts (V). For example, the power voltage Vdd may be 4 V, and a case where the power voltage Vdd is 4 V will be described below in detail.

Reference numeral 701 denotes the source voltage Vs when the gate voltage Vg of the driving transistor 12 is 1 V. Reference numeral 702 denotes the source voltage Vs when the gate voltage Vg of the driving transistor 12 is 2 V. Reference numeral 703 denotes the source voltage Vs when the gate voltage Vg of the driving transistor 12 is 3 V. Reference numeral 704 denotes the source voltage Vs when the gate voltage Vg of the driving transistor 12 is 4 V. Therefore, reference numeral 704 corresponds to reference numeral 603 of the graph of FIG. 6. According to reference numeral 704, the source voltage Vs is changed from about 3 V to several tens of mV.

Because the oscillation device 11 is connected to the source S of the driving transistor 12, the source voltage Vs of the driving transistor 12 is periodically changed when the resistance of the oscillation device 11 is periodically changed according to time. Accordingly, because a difference between the gate voltage Vg and the source voltage Vs is changed in the driving transistor 12, a current flowing to the driving transistor 12 (i.e., a current flowing to the output node N) may not be maintained at a set level. In detail, when the resistance of the oscillation device 11 is increased, a current flowing to the output node N is decreased. When the resistance of the oscillation device 11 is decreased, a current flowing to the output node N is increased, and variation in the voltage of the output node N is relatively decreased. Accordingly, output power of the oscillator 10A′ may be lower than that of the oscillator 10A of FIG. 1.

FIG. 8 is a circuit diagram illustrating the oscillator of FIG. 1 when an external magnetic field is applied in a first direction.

Referring to FIG. 8, an oscillator 10B is a modified example of the oscillator 10A of FIG. 1. The oscillator 10B includes an oscillation device 11, a driving transistor 12, and an amplifier 13. The oscillation device 11, the driving transistor 12, and the amplifier 13 included in the oscillator 10B may be configured in a similar way as those included in the oscillator 10A, and thus a detailed description thereof will be omitted here.

An external magnetic field Hₑₓₜ in the negative x-axis direction may be applied to the oscillator 10B according to example embodiments. The first magnetic layer 111 may be magnetized in the negative x-axis direction due to the external magnetic field Hₑₓₜ. Accordingly, a spin torque in the positive x-axis direction should be applied to the first magnetic layer 111 so as to precess the magnetic moment of the first magnetic layer 111. For this, because electrons e− need to move in the positive y-axis direction (i.e., in a direction from the second magnetic layer 113 to the first magnetic layer 111 in the oscillation device 11) the power voltage Vdd may be applied to the first magnetic layer 111 so that a current I may be applied in the negative y-axis direction (i.e., in a direction from the first magnetic layer 111 to the second magnetic layer 113).

In example embodiments, the output node N of the oscillation device 11 may be connected to the drain D of the driving transistor 12. Thus, although the resistance of the oscillation device 11 is changed according to time, a current flowing to the output node N of the oscillation device 11 may be maintained at a set level, and the voltage of the output node N may be considerably changed. Accordingly, output power of the oscillator 10B may be considerably increased.

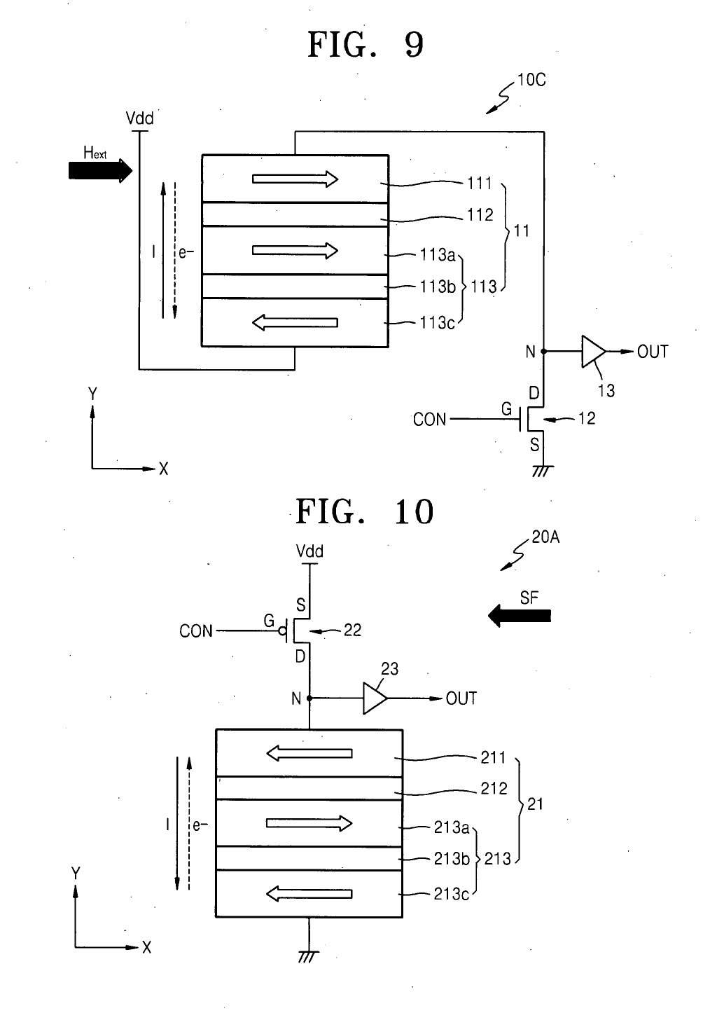

FIG. 9 is a circuit diagram illustrating the oscillator of FIG. 1 when an external magnetic field is applied in a second direction.

Referring to FIG. 9, an oscillator 10C is a modified example of the oscillator 10A of FIG. 1. The oscillator 10C includes an oscillation device 11, a driving transistor 12, and an amplifier 13. The oscillation device 11, the driving transistor 12, and the amplifier 13 included in the oscillator 10C may be configured substantially in a similar way as those included in the oscillator 10A, and thus a detailed description thereof will be omitted here.

An external magnetic field Hₑₓₜ in the positive x-axis direction may be applied to the oscillator 10C according example embodiments. The first magnetic layer 111 may be magnetized in the positive x-axis direction due to the external magnetic field Hₑₓₜ. Accordingly, a spin torque in the negative x-axis direction should be applied to the first magnetic layer 111 so as to precess the magnetic moment of the first magnetic layer 111. For this, because the electrons e− need to move in the negative y-axis direction (i.e., in a direction from the first magnetic layer 111 to the second magnetic layer 113 in the oscillation device 11), the power voltage Vdd may be applied to the second magnetic layer 113 so that a current I may be applied in the positive y-axis direction (i.e., in a direction from the second magnetic layer 113 to the first magnetic layer 111).

In example embodiments, the output node N of the oscillation device 11 may be connected to the drain D of the driving transistor 12. Thus, although the resistance of the oscillation device 11 is changed according to time, a current flowing to the output node N of the oscillation device 11 may be maintained at a set level, and the voltage of the output node N may be considerably changed. Accordingly, output power of the oscillator 10C may be considerably increased.

FIG. 10 is a circuit diagram illustrating an oscillator according to example embodiments.

Referring to FIG. 10, an oscillator 20A may include an oscillation device 21 and a driving transistor 22. The oscillation device 21 may be configured in the form of a spin valve including a first magnetic layer 211, a non-magnetic layer 212, and a second magnetic layer 213. The first magnetic layer 211 of the oscillation device 21 may be disposed above the second magnetic layer 213. Thus, the oscillation device 21 may have a structure in which the second magnetic layer 213, the non-magnetic layer 212, and the first magnetic layer 211 are sequentially stacked. Meanwhile, the configuration of the oscillation device 21 is not limited thereto, and may be modified as illustrated in FIG. 2. The oscillator 20A may further include an amplifier 23.

Although not shown in FIG. 10, electrode layers may be disposed on the first magnetic layer 211 and under the second magnetic layer 213. However, when an electric resistance of the first or second magnetic layer 211 or 213 is sufficiently low, the first or second magnetic layer 211 or 213 itself may be used as an electrode. Thus, it may not be necessary to dispose an additional electrode layer on the first magnetic layer 211 or under the second magnetic layer 213.

The first magnetic layer 211 may be a free layer having a magnetization direction that is variable according to at least one selected from the group consisting of an applied current, an applied voltage, and an applied magnetic field. The first magnetic layer 211 may be configured substantially in a similar way as the first magnetic layer 111 included in the oscillation device 11 of FIG. 1, and thus a detailed description thereof will be omitted here.

The non-magnetic layer 212 may be disposed between the first magnetic layer 211 and the second magnetic layer 213 and may be configured as a conductive layer or an insulating layer. The non-magnetic layer 212 may be configured substantially in a similar way as the non-magnetic layer 112 included in the oscillation device 11 of FIG. 1, and thus a detailed description thereof will be omitted here.

The second magnetic layer 213 may be a pinned layer having a pinned magnetization direction. In example embodiments, the second magnetic layer 213 may have a structure in which a first pinned layer 213a, a separation layer 213b and a second pinned layer 213c are stacked. The first pinned layer 213a, the separation layer 213b and the second pinned layer 213c may be configured substantially in a similar way as the first pinned layer 113a, the separation layer 113b and the second pinned layer 113c included in the oscillation device 11 of FIG. 1, and thus a detailed description thereof will be omitted here.

The driving transistor 22 may be a PMOS transistor having a drain D connected to the oscillation device 21, a gate G to which a control signal CON for controlling driving of the oscillation device 21 is applied, and a source S connected to a power voltage Vdd terminal. When the control signal CON is inactivated, the driving transistor 22 may be turned on, and thus an output voltage of the oscillation device 21 may be provided to the amplifier 23. In example embodiments, the drain D of the driving transistor 22 may be connected to an output node N of the oscillation device 21 (i.e., connected to the first magnetic layer 211).

The amplifier 23 is connected to the output node N of the oscillation device 21 so as to amplify the output voltage of the oscillation device 21 to a set (or threshold) level to provide an output voltage OUT.

Hereinafter, operations of the oscillation device 21 will be described in detail.

In example embodiments, the oscillation device 21 may be connected between the output node N and a ground terminal. In detail, the first magnetic layer 211 may be connected to the output node N, and the second pinned layer 213c of the second magnetic layer 213 may be connected to the ground terminal. Thus, a current I may be applied in the negative y-axis direction (e.g., in a direction from the first magnetic layer 211 to the second magnetic layer 213). Electrons e− may move in the positive y-axis direction (i.e., in a direction from the second magnetic layer 213 to the first magnetic layer 211).

The electrons e− having passed through the second magnetic layer 213 may have a spin direction that is the same as that of the first pinned layer 213a (i.e., a spin direction in the positive x-axis direction), and thus a spin torque in the positive x-axis direction may be applied to the first magnetic layer 211. A magnetic moment of the first magnetic layer 211 may be perturbed due to the spin torque. Even when an additional external magnetic field is not applied to the oscillation device 21, a stray field in the negative x-axis direction may be applied to the first magnetic layer 211 due to the first pinned layer 213a. Thus, a restoring force may be applied to the magnetic moment of the first magnetic layer 211 due to the stray field.

As such, the spin torque in the positive x-axis direction and the stray field in the negative x-axis direction may be applied to the first magnetic layer 211. A force due to the spin torque, which perturbs the magnetic moment of the first magnetic layer 211, and a force due to the stray field, which restores the magnetic moment of the first magnetic layer 211, are balanced. Thus, an axis of the magnetic moment of the first magnetic layer 211 may rotate while tracing a specific track. An axis direction of the magnetic moment may be regarded as a magnetization direction, and a precession of the magnetic moment may be regarded as a rotation of the magnetization direction. An angle formed by magnetization directions of the first magnetic layer 211 and the second magnetic layer 213 may be periodically changed according to the precession of the magnetic moment, and thus an electric resistance of the oscillation device 21 may be periodically changed. As a result, the oscillation device 21 may generate a signal having a set frequency.

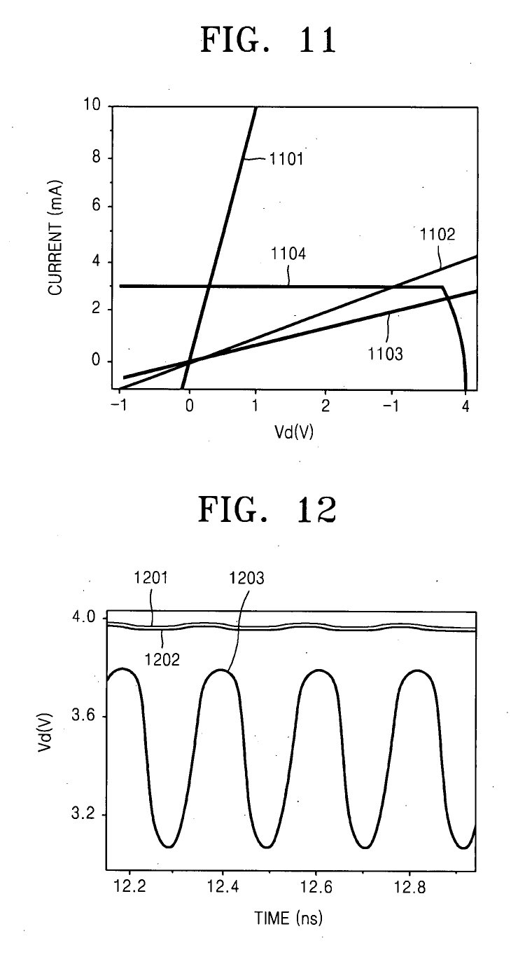

FIG. 11 is a graph showing a relationship between drain voltage and current with respect to the driving transistor included in the oscillator of FIG. 10.

Referring to FIG. 11, an X-axis of the graph represents a drain voltage Vd of the driving transistor 22, and the drain voltage Vd is represented in units of volts (V). Meanwhile, a Y-axis of the graph represents current, and the current is represented in units of amperes (mA). For example, the power voltage Vdd may be 4 V, and a case where the power voltage Vdd is 4 V will be described below in detail.

Reference numeral 1101 denotes a current (=Vd/100) flowing to the oscillation device 21 when the electric resistance of the oscillation device 21 is 100Ω. Reference numeral 1102 denotes a current (=Vd/1000) flowing to the oscillation device 21 when the electric resistance of the oscillation device 21 is 1000Ω. Reference numeral 1103 denotes a current (=Vd/1500) flowing to the oscillation device 21 when the electric resistance of the oscillation device 21 is 1500Ω. Reference numeral 1104 denotes a current flowing to the drain D of the driving transistor 22 when a gate voltage of the driving transistor 22 is 3 V.

According to a portion of reference numeral 1104 between reference numeral 1101 and reference numeral 1102, when the electric resistance of the oscillation device 21 is changed from 100Ω to 1000Ω, a current flowing to the drain D of the driving transistor 22 is maintained constant at about 3 mA, and the drain voltage Vd is changed from about 0 V to about 3 V. According to a portion of reference numeral 1104 between reference numeral 1102 and reference numeral 1103, when the electric resistance of the oscillation device 21 is changed from 1000Ω to 1500Ω, a current flowing to the drain D of the driving transistor 22 is maintained constant at about 3 mA and then is decreased to about 2 mA when the drain voltage Vd becomes close to 4 V, and the drain voltage Vd is changed from about 3 V to about 4 V.

FIG. 12 is a graph showing a relationship between time and drain voltage with respect to the driving transistor included in the oscillator of FIG. 10.

Referring to FIG. 12, an X-axis of the graph represents time in units of seconds (ns). Meanwhile, a Y-axis of the graph represents the drain voltage Vd of the driving transistor 22, and the drain voltage Vd is represented in units of volts (V). For example, the power voltage Vdd may be 4 V, and a case where the power voltage Vdd is 4 V will be described below in detail.

Reference numeral 1201 denotes the drain voltage Vd when a gate voltage Vg of the driving transistor 22 is 1 V. Reference numeral 1202 denotes the drain voltage Vd when the gate voltage Vg of the driving transistor 22 is 2 V. Reference numeral 1203 denotes the drain voltage Vd when the gate voltage Vg of the driving transistor 22 is 3 V. Therefore, reference numeral 1203 corresponds to reference numeral 1104 in the graph of FIG. 11. According to reference numeral 1203, because the drain voltage Vd is periodically changed from about 3.1 V to about 3.8 V according to time, the drain voltage Vd varies by about 700 mV.

According to example embodiments, because the oscillation device 21 is connected to the drain D of the driving transistor 22, although the resistance of the oscillation device 21 is periodically changed according to time, the gate voltage Vg and a source voltage of the driving transistor 22 are not changed. Accordingly, a current flowing to the driving transistor 22 (i.e., a current flowing to the output node N) may be maintained at a constant level, and the drain voltage Vd of the driving transistor 22 (i.e., a voltage of the output node N) may be periodically changed by about several hundreds of mV according to variation in the resistance of the oscillation device 21. Because the output power of the oscillation device 21 is proportional to a square of the voltage of the output node N, the output power of the oscillation device 21 may be great when the voltage of the output node N varies greatly.

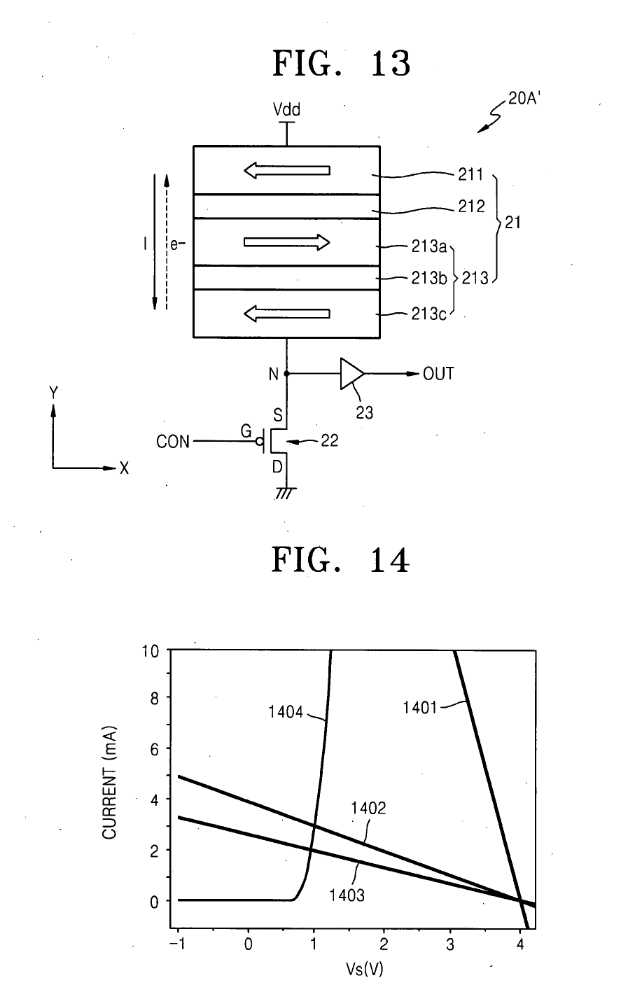

FIG. 13 is a circuit diagram illustrating an oscillator according to a comparative example with respect to the oscillator of FIG. 10.

Referring to FIG. 13, an oscillator 20A′ may include an oscillation device 21, a driving transistor 22 and an amplifier 23. The oscillation device 21, the driving transistor 22 and the amplifier 23 included in the oscillator 20A′ according to example embodiments may be configured substantially in a similar way as the oscillation device 21, the driving transistor 22 and the amplifier 23 included in the oscillator 20A of FIG. 10. The oscillation device 21 of the oscillator 20A of FIG. 10 is connected to the drain D of the driving transistor 22, while the oscillator 20A′ is connected to the source S of the driving transistor 22.

FIG. 14 is a graph showing a relationship between source voltage and current with respect to the driving transistor included in the oscillator of FIG. 13.

Referring to FIG. 14, an X-axis of the graph represents a source voltage Vs of the driving transistor 22, and the source voltage Vs is represented in units of volts (V). Meanwhile, a Y-axis of the graph represents current, and the current is represented in units of amperes (mA). For example, the power voltage Vdd may be 4 V, and a case where the power voltage Vdd is 4 V will be described below in detail

Reference numeral 1401 denotes a current (=(4−Vs)/100) flowing to the oscillation device 21 when the electric resistance of the oscillation device 21 is 100Ω. Reference numeral 1402 denotes a current (=(4−Vs)/1000) flowing to the oscillation device 21 when the electric resistance of the oscillation device 21 is 1000Ω. Reference numeral 1403 denotes a current (=(4−Vs)/1500) flowing to the oscillation device 21 when the electric resistance of the oscillation device 21 is 1500Ω. Reference numeral 1404 denotes a current flowing to the drain D of the driving transistor 22 when the gate voltage Vg of the driving transistor 22 is 0 V.

According to a portion of reference numeral 1404 between reference numeral 1402 and reference numeral 1403, when the electric resistance of the oscillation device 21 is changed from 1000Ω to 1500Ω, the source voltage Vs is decreased, and a current flowing to the drain D of the driving transistor 22 is also decreased.

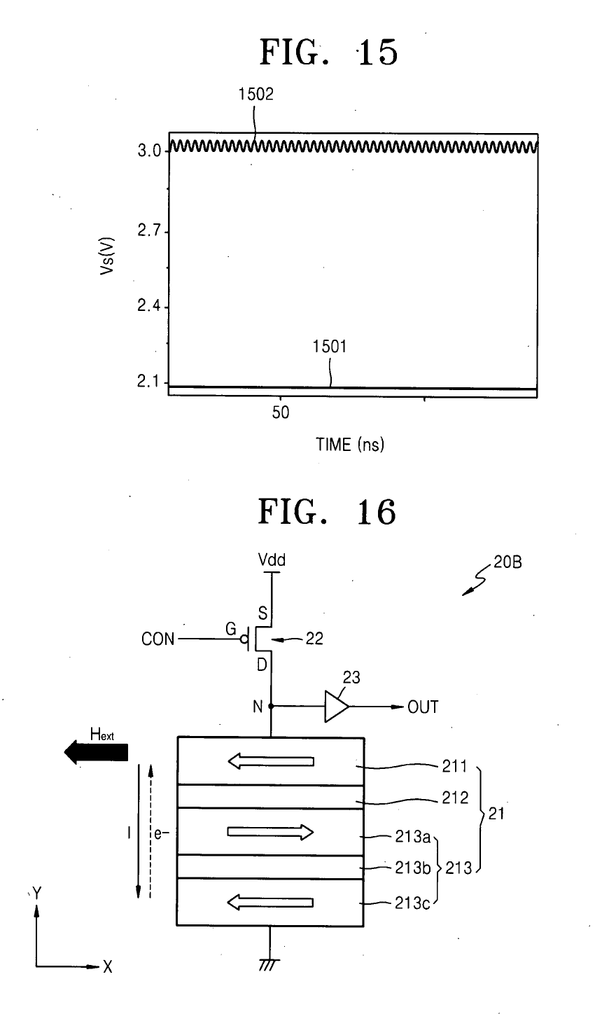

FIG. 15 is a graph showing a relationship between time and source voltage with respect to the driving transistor included in the oscillator of FIG. 13.

Referring to FIG. 15, an X-axis of the graph represents time in units of seconds (ns). Meanwhile, a Y-axis of the graph represents the source voltage Vs of the driving transistor 22, and the source voltage Vs is represented in units of volts (V). For example, the power voltage Vdd may be 4 V, and a case where the power voltage Vdd is 4 V will be described below in detail.

Reference numeral 1501 denotes the source voltage Vs when the gate voltage Vg of the driving transistor 22 is 1 V. Reference numeral 1502 denotes the source voltage Vs when the gate voltage Vg of the driving transistor 22 is 0 V. Therefore, reference numeral 1502 corresponds to reference numeral 1404 of the graph of FIG. 14. At this time, according to reference numeral 1502, the source voltage Vs is changed from about 3 V to several tens of mV.

According to example embodiments, because the oscillation device 21 is connected to the source S of the driving transistor 22, the source voltage Vs of the driving transistor 22 is periodically changed when the resistance of the oscillation device 21 is periodically changed according to time. Accordingly, because a difference between the gate voltage Vg and the source voltage Vs is changed in the driving transistor 22, a current flowing to the driving transistor 22 (i.e., a current flowing to the output node N) may not be maintained at a set level. In detail, when the resistance of the oscillation device 21 is increased, a current flowing to the output node N is decreased. When the resistance of the oscillation device 21 is decreased, a current flowing to the output node N is increased, and variation in the voltage of the output node N is relatively decreased. Accordingly, output power of the oscillator 20A′ may be lower than that of the oscillator 20A of FIG. 10.

FIG. 16 is a circuit diagram illustrating the oscillator 20A of FIG. 10 when an external magnetic field is applied in a first direction.

Referring to FIG. 16, an oscillator 20B, which is a modified example of the oscillator 20A of FIG. 10, may include an oscillation device 21, a driving transistor 22 and an amplifier 23. The oscillation device 21, the driving transistor 22 and the amplifier 23 included in the oscillator 20B may be configured substantially in a similar way as those included in the oscillator 20A, and thus a detailed description thereof will be omitted here.

An external magnetic field Hₑₓₜ in the negative x-axis direction may be applied to the oscillator 20B according to example embodiments. The first magnetic layer 211 may be magnetized in the negative x-axis direction due to the external magnetic field Hₑₓₜ. Accordingly, a spin torque in the positive x-axis direction should be applied to the first magnetic layer 211 so as to precess the magnetic moment of the first magnetic layer 211. For this, because electrons e− need to move in the positive y-axis direction (i.e., in a direction from the second magnetic layer 213 to the first magnetic layer 211) in the oscillation device 21, a ground voltage may be applied to the second magnetic layer 213 so that a current I may be applied in the negative y-axis direction (i.e., in a direction from the first magnetic layer 211 to the second magnetic layer 213).

In example embodiments, the output node N of the oscillation device 21 may be connected to the drain D of the driving transistor 22. Thus, although the resistance of the oscillation device 21 is changed according to time, a current flowing to the output node N of the oscillation device 21 may be maintained at a set level, and the voltage of the output node N may be considerably changed. Accordingly, output power of the oscillator 20B may be considerably increased.

FIG. 17 is a circuit diagram illustrating the oscillator of FIG. 10 when an external magnetic field is applied in a second direction.

Referring to FIG. 17, an oscillator 20C is a modified example of the oscillator 20A of FIG. 10. The oscillator 20C includes an oscillation device 21, a driving transistor 22 and an amplifier 23. The oscillation device 21, the driving transistor 22 and the amplifier 23 included in the oscillator 20C may be configured substantially in a similar way as those included in the oscillator 20A, and thus a detailed description thereof will be omitted here.

An external magnetic field Hₑₓₜ in the positive x-axis direction may be applied to the oscillator 20C according to example embodiments. The first magnetic layer 211 may be magnetized in the positive x-axis direction due to the external magnetic field Hₑₓₜ. Accordingly, a spin torque in the negative x-axis direction should be applied to the first magnetic layer 211 so as to precess the magnetic moment of the first magnetic layer 211. For this, because electrons e− need to move in the negative y-axis direction (i.e., in a direction from the first magnetic layer 211 to the second magnetic layer 213) in the oscillation device 21, the ground voltage may be applied to the first magnetic layer 211 so that a current I may be applied in the positive y-axis direction (i.e., in a direction from second magnetic layer 213 to the first magnetic layer 211).

In example embodiments, the output node N of the oscillation device 21 may be connected to the drain D of the driving transistor 22. Thus, although the resistance of the oscillation device 21 is changed according to time, a current flowing to the output node N of the oscillation device 21 may be maintained at a set level, and the voltage of the output node N may be considerably changed. Accordingly, output power of the oscillator 20C may be considerably increased.

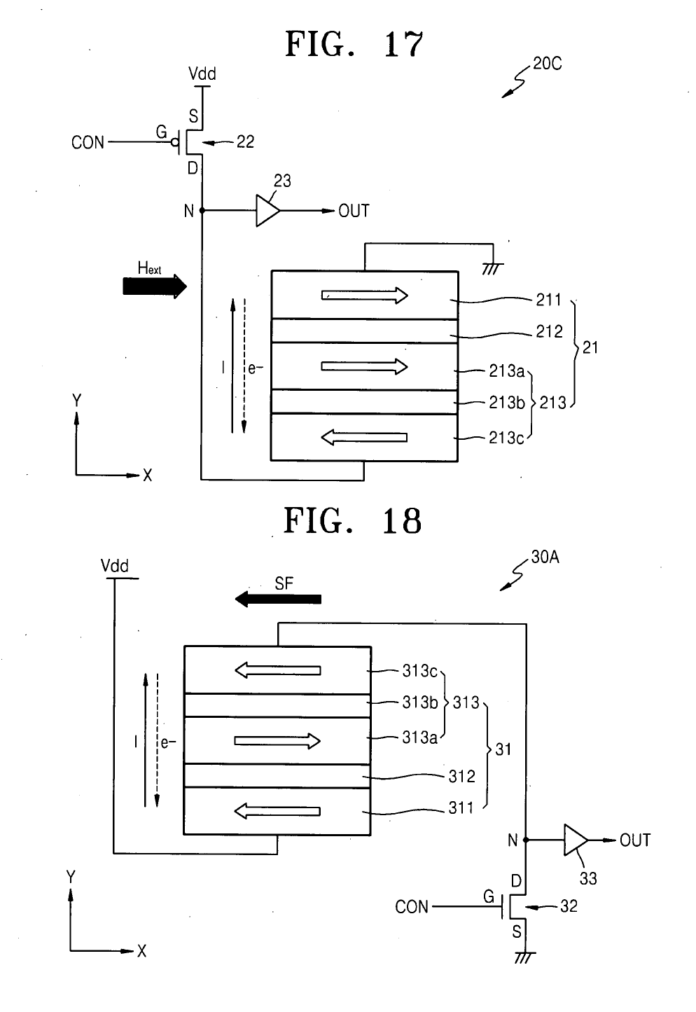

FIG. 18 is a circuit diagram illustrating an oscillator according to example embodiments.

Referring to FIG. 18, the oscillator 30A may include an oscillation device 31 and a driving transistor 32. The oscillation device 31 may be configured in the form of a spin valve including a first magnetic layer 311, a non-magnetic layer 312 and a second magnetic layer 313. The first magnetic layer 311 of the oscillation device 31 may be disposed below the second magnetic layer 313. Thus, the oscillation device 31 may have a structure in which the first magnetic layer 311, the non-magnetic layer 312 and the second magnetic layer 313 are sequentially stacked. Meanwhile, the configuration of the oscillation device 31 is not limited thereto and may be modified as illustrated in FIG. 2. The oscillator 30A may further include an amplifier 33.

Although not shown in FIG. 18, electrode layers may be disposed under the first magnetic layer 311 and on the second magnetic layer 313. However, when an electric resistance of the first or second magnetic layer 311 or 313 is sufficiently low, the first or second magnetic layer 311 or 313 itself may be used as an electrode. Thus, there may be no need to dispose an additional electrode layer under the first magnetic layer 311 or on the second magnetic layer 313.

The first magnetic layer 311 may be a free layer having a magnetization direction that is variable according to at least one selected from the group consisting of an applied current, an applied voltage, and an applied magnetic field. The first magnetic layer 311 may be configured substantially in a similar way as the first magnetic layer 111 included in the oscillation device 11 of FIG. 1, and thus a detailed description thereof will be omitted here.

The non-magnetic layer 312 may be disposed between the first magnetic layer 311 and the second magnetic layer 313 and may be configured as a conductive layer or an insulating layer. The non-magnetic layer 312 may be configured substantially in a similar way as the non-magnetic layer 112 included in the oscillation device 11 of FIG. 1, and thus a detailed description thereof will be omitted here.

The second magnetic layer 313 may be a pinned layer having a pinned magnetization direction. In example embodiments, the second magnetic layer 313 may have a structure in which a first pinned layer 313a, a separation layer 313b and a second pinned layer 313c are stacked. The first pinned layer 313a, the separation layer 313b and the second pinned layer 313c may be configured substantially in a similar way as the first pinned layer 113a, the separation layer 113b and the second pinned layer 113c included in the oscillation device 11 of FIG. 1, and thus a detailed description thereof will be omitted here.

The driving transistor 32 may be an NMOS transistor having a drain D connected to the oscillation device 31, a gate G to which a control signal CON for controlling driving of the oscillation device 31 is applied, and a source S connected to a ground terminal. When the control signal CON is activated, the driving transistor 32 may be turned on, and thus an output voltage of the oscillation device 31 may be provided to the amplifier 33. In example embodiments, the drain D of the driving transistor 32 may be connected to an output node N of the oscillation device 31 (i.e., connected to the second magnetic layer 313).

The amplifier 33 is connected to the output node N of the oscillation device 31 so as to amplify the output voltage of the oscillation device 31 to a set (or threshold) level to provide an output voltage OUT.

Hereinafter, operations of the oscillation device 31 will be described in detail.

In example embodiments, the oscillation device 31 may be connected between a power voltage Vdd terminal and the output node N. In detail, the first magnetic layer 311 is connected to the power voltage Vdd terminal, and thus a power voltage Vdd may be applied to the first magnetic layer 311, and the second pinned layer 313c of the second magnetic layer 313 may be connected to the output node N. Thus, a current I may be applied in the positive y-axis direction, (i.e., in a direction from the first magnetic layer 311 to the second magnetic layer 313), and electrons e− may move in the negative y-axis direction (i.e., in a direction from the second magnetic layer 313 to the first magnetic layer 311).

The electrons e− having passed through the second magnetic layer 313 may have a spin direction that is the same as that of the first pinned layer 313a (i.e., a spin direction in the positive x-axis direction), and thus a spin torque in the positive x-axis direction may be applied to the first magnetic layer 311. A magnetic moment of the first magnetic layer 311 may be perturbed due to the spin torque. Meanwhile, even when an additional external magnetic field is not applied to the oscillation device 31, a stray field SF in the negative x-axis direction may be applied to the first magnetic layer 311 due to the first pinned layer 313a. Thus, a restoring force may be applied to the magnetic moment of the first magnetic layer 311 due to the stray field SF.

As such, the spin torque in the positive x-axis direction and the stray field in the negative x-axis direction may be applied to the first magnetic layer 311. A force due to the spin torque, which perturbs the magnetic moment of the first magnetic layer 311, and a force due to the stray field, which restores the magnetic moment of the first magnetic layer 311, are balanced. Thus, an axis of the magnetic moment of the first magnetic layer 311 may rotate while tracing a specific track. At this time, an axis direction of the magnetic moment may be regarded as a magnetization direction, and a precession of the magnetic moment may be regarded as a rotation of the magnetization direction. An angle formed by magnetization directions of the first magnetic layer 311 and the second magnetic layer 313 may be periodically changed according to the precession of the magnetic moment, and thus an electric resistance of the oscillation device 31 may be periodically changed. As a result, the oscillation device 31 may generate a signal having a set frequency.

In example embodiments, the output node N of the oscillation device 31 may be connected to the drain D of the driving transistor 32. Thus, although the resistance of the oscillation device 31 is changed according to time, a current flowing to the output node N of the oscillation device 31 may be maintained at a set level, and a voltage of the output node N may be considerably changed. Accordingly, output power of the oscillator 30A may be considerably increased.

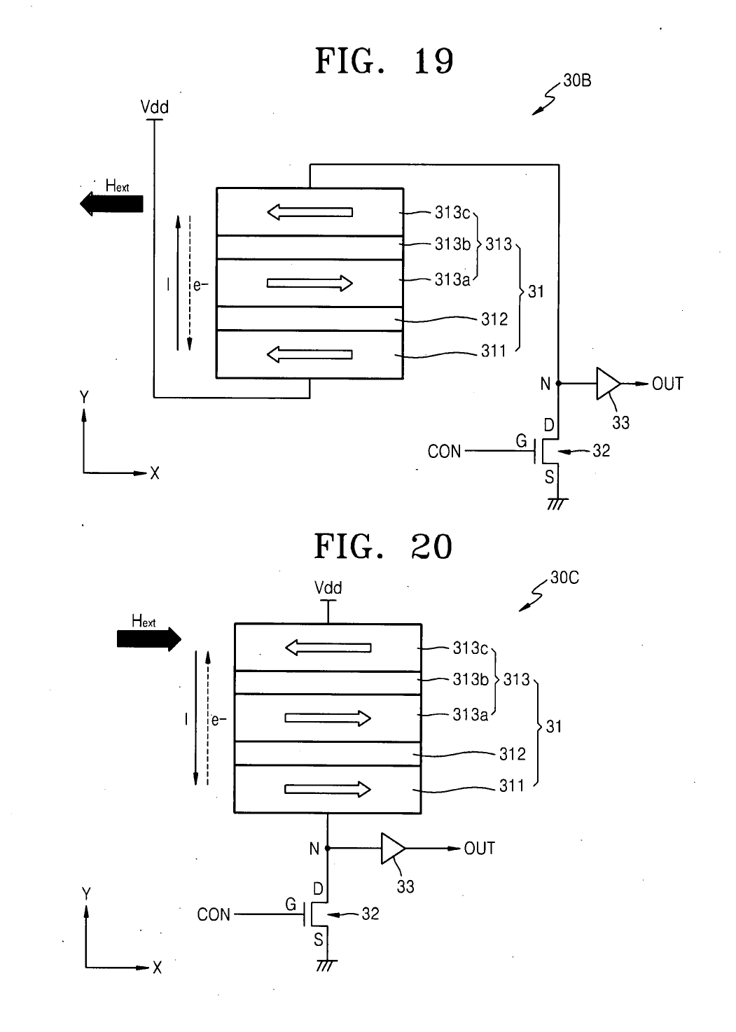

FIG. 19 is a circuit diagram illustrating the oscillator of FIG. 18 when an external magnetic field is applied in a first direction.

Referring to FIG. 19, an oscillator 30B, which is a modified example of the oscillator 30A of FIG. 18, may include an oscillation device 31, a driving transistor 32 and an amplifier 33. The oscillation device 31, the driving transistor 32 and the amplifier 33 included in the oscillator 30B may be configured substantially in a similar way as those included in the oscillator 30A, and thus a detailed description thereof will be omitted here.

An external magnetic field Hₑₓₜ in the negative x-axis direction may be applied to the oscillator 30B according to example embodiments. The first magnetic layer 311 may be magnetized in the negative x-axis direction due to the external magnetic field Hₑₓₜ. Accordingly, a spin torque in the positive x-axis direction should be applied to the first magnetic layer 311 so as to precess the magnetic moment of the first magnetic layer 311. For this, because electrons e− need to move in the negative y-axis direction (i.e., in a direction from the second magnetic layer 313 to the first magnetic layer 311 in the oscillation device 31) the power voltage Vdd may be applied to the first magnetic layer 311 so that a current I may be applied in the positive y-axis direction (i.e., in a direction from the first magnetic layer 311 to the second magnetic layer 313).

In example embodiments, the output node N of the oscillation device 31 may be connected to the drain D of the driving transistor 32. Thus, although the resistance of the oscillation device 31 is changed according to time, a current flowing to the output node N of the oscillation device 31 may be maintained at a set level, and the voltage of the output node N may be considerably changed. Accordingly, output power of the oscillator 30B may be considerably increased.

FIG. 20 is a circuit diagram illustrating the oscillator of FIG. 18 when an external magnetic field is applied in a second direction.

Referring to FIG. 20, an oscillator 30C is a modified example of the oscillator 30A of FIG. 18. The oscillator 30C includes an oscillation device 31, a driving transistor 32 and an amplifier 33. The oscillation device 31, the driving transistor 32 and the amplifier 33 included in the oscillator 30C may be configured substantially in a similar way as those included in the oscillator 30A, and thus a detailed description thereof will be omitted here.

An external magnetic field Hₑₓₜ in the positive x-axis direction may be applied to the oscillator 30C according to example embodiments. The first magnetic layer 311 may be magnetized in the positive x-axis direction due to the external magnetic field Hₑₓₜ. Accordingly, a spin torque in the negative x-axis direction should be applied to the first magnetic layer 311 so as to precess the magnetic moment of the first magnetic layer 311. For this, because electron e− need to move in the positive y-axis direction (i.e., in a direction from the first magnetic layer 311 to the second magnetic layer 313 in the oscillation device 31), the power voltage Vdd may be applied to the second magnetic layer 313 so that a current I may be applied in the negative y-axis direction (i.e., in a direction from second magnetic layer 313 to the first magnetic layer 311).

In example embodiments, the output node N of the oscillation device 31 may be connected to the drain D of the driving transistor 32. Thus, although the resistance of the oscillation device 31 is changed according to time, a current flowing to the output node N of the oscillation device 31 may be maintained at a set level, and the voltage of the output node N may be considerably changed. Accordingly, output power of the oscillator 30C may be considerably increased.

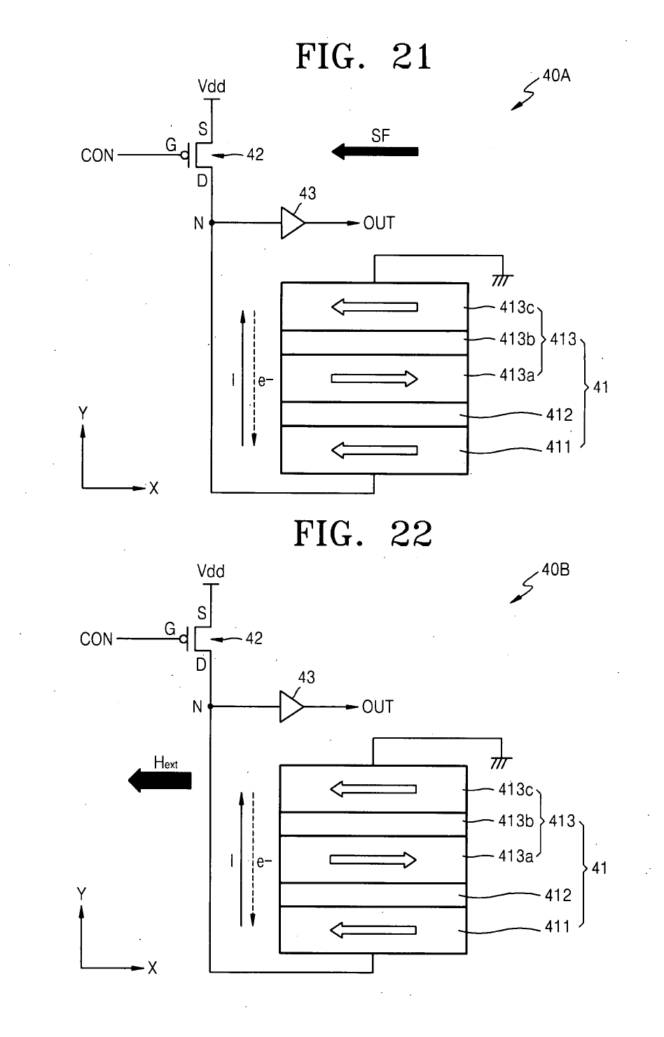

FIG. 21 is a circuit diagram illustrating an oscillator according to example embodiments.

Referring to FIG. 21, an oscillator 40A may include an oscillation device 41 and a driving transistor 42. The oscillation device 41 may be configured in the form of a spin valve including a first magnetic layer 411, a non-magnetic layer 412 and a second magnetic layer 413. The first magnetic layer 411 of the oscillation device 41 may be disposed below the second magnetic layer 413, and thus the oscillation device 41 may have a structure in which the first magnetic layer 411, the non-magnetic layer 412, and the second magnetic layer 413 are sequentially stacked. Meanwhile, the configuration of the oscillation device 41 is not limited thereto and may be modified as illustrated in FIG. 2 (e.g., to include a ferromagnetic layer and an antiferromagnetic layer). The oscillator 40A may further include an amplifier 43.

Although not shown in FIG. 21, electrode layers may be disposed under the first magnetic layer 411 and on the second magnetic layer 413. However, when an electric resistance of the first or second magnetic layer 411 or 413 is sufficiently low, the first or second magnetic layer 411 or 413 itself may be used as an electrode. Thus, it may not be necessary to dispose an additional electrode layer on the first or second magnetic layer 411 or 413.

The first magnetic layer 411 may be a free layer having a magnetization direction that is variable according to at least one selected from the group consisting of an applied current, an applied voltage and an applied magnetic field. The first magnetic layer 411 may be configured substantially in a similar way as the first magnetic layer 411 included in the oscillation device 11 of FIG. 1, and thus a detailed description thereof will be omitted here.

The non-magnetic layer 412 may be disposed between the first magnetic layer 411 and the second magnetic layer 413 and may be configured as a conductive layer or an insulating layer. The non-magnetic layer 412 may be configured substantially in a similar way as the non-magnetic layer 112 included in the oscillation device 11 of FIG. 1, and thus a detailed description thereof will be omitted here.

The second magnetic layer 413 may be a pinned layer having a pinned magnetization direction. In example embodiments, the second magnetic layer 413 may have a structure in which a first pinned layer 413a, a separation layer 413b and a second pinned layer 413c are stacked. The first pinned layer 413a, the separation layer 413b and the second pinned layer 413c may be configured substantially in a similar way as the first pinned layer 113a, the separation layer 113b and the second pinned layer 113c included in the oscillation device 11 of FIG. 1, and thus a detailed description thereof will be omitted here.

The driving transistor 42 may be a PMOS transistor having a drain D connected to the oscillation device 41, a gate G to which a control signal CON for controlling driving of the oscillation device 41 is applied, and a source S connected to a power voltage Vdd terminal. When the control signal CON is inactivated, the driving transistor 42 may be turned on, and thus an output voltage of the oscillation device 41 may be provided to the amplifier 43. In example embodiments, the drain D of the driving transistor 42 may be connected to an output node N of the oscillation device 41 (i.e., to the second magnetic layer 413).

The amplifier 43 is connected to the output node N of the oscillation device 41 so as to amplify the output voltage of the oscillation device 41 to a set level to provide an output voltage OUT.

Hereinafter, operations of the oscillation device 41 will be described in detail.

In example embodiments, the oscillation device 41 may be connected between the output node N and a ground terminal. In detail, the first magnetic layer 411 is connected to the output node N, and the second pinned layer 413c of the second magnetic layer 413 may be connected to the ground terminal. Thus, a current I may be applied in the positive y-axis direction (i.e., in a direction from the first magnetic layer 411 to the second magnetic layer 413), and electrons e− may move in the negative y-axis direction (i.e., in a direction from the second magnetic layer 413 to the first magnetic layer 411).

The electron e− having passed through the second magnetic layer 413 may have a spin direction that is the same as that of the first pinned layer 413a (i.e., a spin direction in the positive x-axis direction), and thus a spin torque in the positive x-axis direction may be applied to the first magnetic layer 411. A magnetic moment of the first magnetic layer 411 may be perturbed due to the spin torque. Meanwhile, even when an additional external magnetic field is not applied to the oscillation device 41, a stray field SF in the negative x-axis direction may be applied to the first magnetic layer 411 due to the first pinned layer 413a. Thus, a restoring force may be applied to the magnetic moment of the first magnetic layer 411 due to the stray field SF.

As such, the spin torque in the positive x-axis direction and the stray field in the negative x-axis direction may be applied to the first magnetic layer 411. A force due to the spin torque, which perturbs the magnetic moment of the first magnetic layer 411, and a force due to the stray field, which restores the magnetic moment of the first magnetic layer 411, are balanced, and thus an axis of the magnetic moment of the first magnetic layer 411 may rotate while tracing a specific track. At this time, an axis direction of the magnetic moment may be regarded a magnetization direction, and a precession of the magnetic moment may be regarded as a rotation of the magnetization direction. An angle formed by magnetization directions of the first magnetic layer 411 and the second magnetic layer 413 may be periodically changed according to the precession of the magnetic moment, and thus an electric resistance of the oscillation device 41 may be periodically changed. As a result, the oscillation device 41 may generate a signal having a set frequency.

FIG. 22 is a circuit diagram illustrating the oscillator of FIG. 21 when an external magnetic field is applied in a first direction.

Referring to FIG. 22, an oscillator 40B, which is a modified example of the oscillator 40A of FIG. 21, may include an oscillation device 41, a driving transistor 42 and an amplifier 43. The oscillation device 41, the driving transistor 42 and the amplifier 43 included in the oscillator 40B may be configured substantially in a similar way as those included in the oscillator 40A, and thus a detailed description thereof will be omitted here.

An external magnetic field Hₑₓₜ in the negative x-axis direction may be applied to the oscillator 40B according to example embodiments. The first magnetic layer 411 may be magnetized in the negative x-axis direction due to the external magnetic field Hₑₓₜ. Accordingly, a spin torque in the x-axis direction should be applied to the first magnetic layer 411 so as to precess the magnetic moment of the first magnetic layer 411. For this, because electron e− need to move in the negative y-axis direction (i.e., in a direction from the second magnetic layer 413 to the first magnetic layer 411 in the oscillation device 41), a ground voltage may be applied to the second magnetic layer 413 so that a current I may be applied in the positive y-axis direction (i.e., in a direction from the first magnetic layer 411 to the second magnetic layer 413).

In example embodiments, the output node N of the oscillation device 41 may be connected to the drain D of the driving transistor 42. Thus, although the resistance of the oscillation device 41 is changed according to time, a current flowing to the output node N of the oscillation device 41 may be maintained at a set level, and the voltage of the output node N may be considerably changed. Accordingly, output power of the oscillator 40B may be considerably increased.

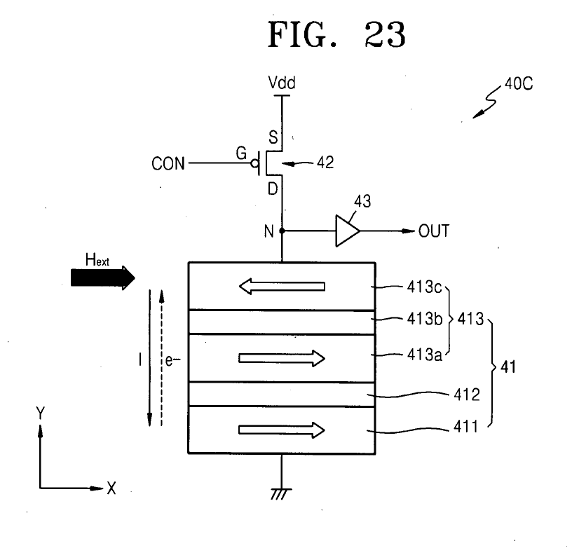

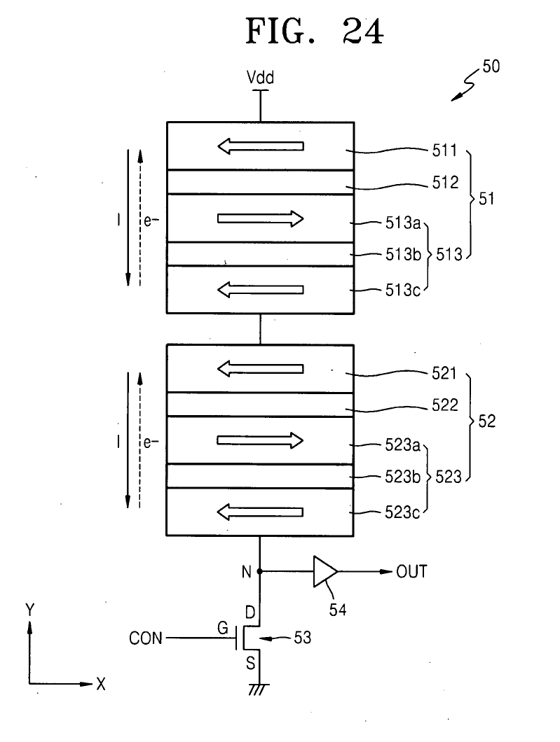

FIG. 23 is a circuit diagram illustrating the oscillator of FIG. 21 when an external magnetic field is applied in a second direction.

Referring to FIG. 23, an oscillator 40C is a modified example of the oscillator 40A of FIG. 21. The oscillator 40C includes an oscillation device 41, a driving transistor 42 and an amplifier 43. The oscillation device 41, the driving transistor 42 and the amplifier 43 included in the oscillator 40C may be configured substantially in a similar way as those included in the oscillator 40A, and thus a detailed description thereof will be omitted here.

An external magnetic field Hₑₓₜ in the positive x-axis direction may be applied to the oscillator 40C according to example embodiments. The first magnetic layer 411 may be magnetized in the positive x-axis direction due to the external magnetic field Hₑₓₜ. Accordingly, a spin torque in the negative x-axis direction should be applied to the first magnetic layer 411 so as to precess the magnetic moment of the first magnetic layer 411. For this, because electrons e− needs to move in the positive y-axis direction (i.e., in a direction from the first magnetic layer 411 to the second magnetic layer 413 in the oscillation device 41), the ground voltage may be applied to the first magnetic layer 411 so that a current I may be applied in the negative y-axis direction (i.e., in a direction from second magnetic layer 413 to the first magnetic layer 411).

In example embodiments, the output node N of the oscillation device 41 may be connected to the drain D of the driving transistor 42. Thus, although the resistance of the oscillation device 41 is changed according to time, a current flowing to the output node N of the oscillation device 41 may be maintained at a set level, and the voltage of the output node N may be considerably changed. Accordingly, output power of the oscillator 40C may be considerably increased.

FIG. 24 is a circuit diagram illustrating an oscillator including a plurality of oscillation devices connected to each other in series according to example embodiments.

Referring to FIG. 24, an oscillator 50 may include first and second oscillation devices 51 and 52 connected to each other in series, and a driving transistor 53. However, example embodiments are not limited thereto, and the oscillator 50 may include at least three oscillation devices connected to one another in series. The oscillator 50 may further include an amplifier 54.

The first oscillation device 51 may include a first magnetic layer 511, a non-magnetic layer 512 and a second magnetic layer 513. The second oscillation device 52 may include a first magnetic layer 521, a non-magnetic layer 522 and a second magnetic layer 523. The first magnetic layer 511 of the first oscillation device 51 may be disposed above the second magnetic layer 513, and the first magnetic layer 521 of the second oscillation device 52 may be disposed above the second magnetic layer 523. However, example embodiments are not limited thereto, and thus positions of the second magnetic layers 513 and 523 and positions of the first magnetic layers 511 and 521 may be changed. Meanwhile the configurations of the first and second oscillation devices 51 and 52 are not limited thereto, and may be changed as illustrated in FIG. 2.

The first magnetic layers 511 and 521 may be free layers having magnetization directions that are variable according to at least one selected from the group consisting of an applied current, an applied voltage and an applied magnetic field. The first magnetic layers 511 and 521 may be configured substantially in a similar way as the first magnetic layer 111 included in the oscillation device 11 of FIG. 1, and thus a detailed description thereof will be omitted here.

The non-magnetic layer 512 may be disposed between the first magnetic layer 511 and the second magnetic layer 513, and the non-magnetic layer 522 may be disposed between the first magnetic layer 521 and the second magnetic layer 523. The non-magnetic layers 512 and 522 may be configured as conductive layers or insulating layers. The non-magnetic layers 512 and 522 may be configured substantially in a similar way as the non-magnetic layer 112 included in the oscillation device 11 of FIG. 1, and thus a detailed description thereof will be omitted here.

The second magnetic layers 513 and 523 may be pinned layers having a pinned magnetization direction. In example embodiments, the second magnetic layer 513 may include a structure in which a first pinned layer 513a, a separation layer 513b and a second pinned layer 513c are stacked. The second magnetic layer 523 may include a structure in which a first pinned layer 523a, a separation layer 523b and a second pinned layer 523c are stacked. The first pinned layers 513a and 523a, the separation layers 513b and 523b and the second pinned layers 513c and 523c may be configured substantially in a similar way as the first pinned layer 113a, the separation layer 113b and the second pinned layer 113c included in the oscillation device 11 of FIG. 1, and thus a detailed description thereof will be omitted here.

The driving transistor 53 may be an NMOS transistor having a drain D connected to the second oscillation device 52, a gate G to which a control signal CON for controlling driving of the first and second oscillation devices 51 and 52 is applied, and a source S connected to a ground terminal. When the control signal CON is activated, the driving transistor 53 may be turned on, and thus output voltages of the first and second oscillation devices 51 and 52 may be provided to the amplifier 54. In example embodiments, the drain D of the driving transistor 53 may be connected to an output node N of the second oscillation device 52 (i.e., to the second magnetic layer 523).

The amplifier 54 is connected to the output node N of the second oscillation device 52 so as to amplify the output voltage of the second oscillation device 52 to a set level to provide an output voltage OUT.

In example embodiments, the output node N of the second oscillation device 52 may be connected to the drain D of the driving transistor 53. Thus, although a resistance of the second oscillation device 52 is changed according to time, a current flowing to the output node N of the second oscillation device 52 may be maintained to a set level, and a voltage of the output node N may be considerably changed. Accordingly, output power of the oscillator 50 may be considerably increased.

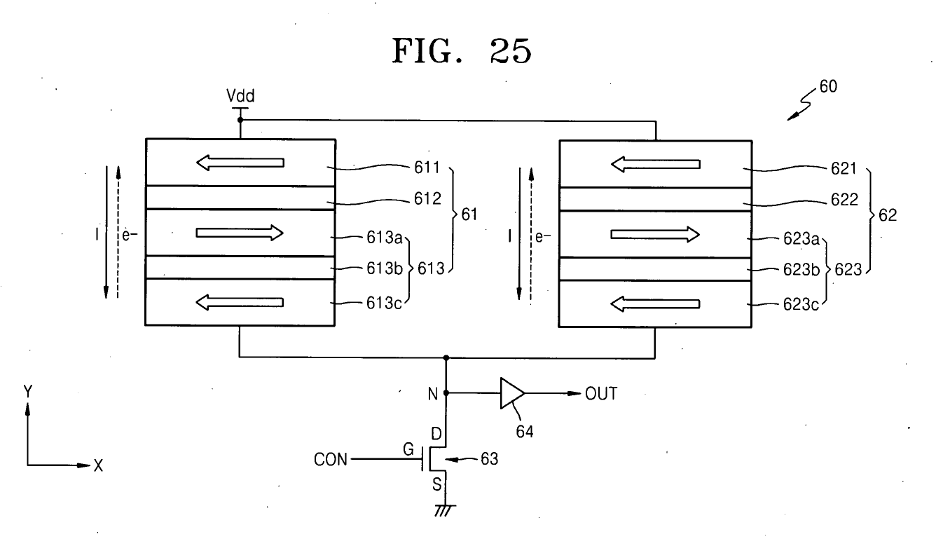

FIG. 25 is a circuit diagram illustrating an oscillator including a plurality of oscillation devices connected to each other in parallel according to example embodiments.

Referring to FIG. 25, an oscillator 60 may include first and second oscillation devices 61 and 62, which are connected to each other in parallel, and a driving transistor 63. However, example embodiments are not limited thereto, and the oscillator 60 may include at least three oscillation devices connected to one another in parallel. The oscillator 60 may further include an amplifier 64.

The first oscillation device 61 may include a first magnetic layer 611, a non-magnetic layer 612 and a second magnetic layer 613. The second oscillation device 62 may include a first magnetic layer 621, a non-magnetic layer 622 and a second magnetic layer 623. The first magnetic layer 611 of the first oscillation device 61 may be disposed above the second magnetic layer 613, and the first magnetic layer 621 of the second oscillation device 62 may be disposed above the second magnetic layer 623. However, example embodiments are not limited thereto, and thus positions of the second magnetic layers 613 and 623 and positions of the first magnetic layers 611 and 621 may be changed. Meanwhile the configurations of the first and second oscillation devices 61 and 62 are not limited thereto, and may be changed as illustrated in FIG. 2.

The first magnetic layers 611 and 621 may be free layers having magnetization directions that are variable according to at least one selected from the group consisting of an applied current, an applied voltage and an applied magnetic field. The first magnetic layers 611 and 621 may be configured substantially in a similar way as the first magnetic layer 111 included in the oscillation device 11 of FIG. 1, and thus a detailed description thereof will be omitted here.

The non-magnetic layer 612 may be disposed between the first magnetic layer 611 and the second magnetic layer 613, and the non-magnetic layer 622 may be disposed between the first magnetic layer 621 and the second magnetic layer 623. The non-magnetic layers 612 and 622 may be configured as conductive layers or insulating layers. The non-magnetic layers 612 and 622 may be configured substantially in a similar way as the non-magnetic layer 112 included in the oscillation device 11 of FIG. 1, and thus a detailed description thereof will be omitted here.

The second magnetic layers 613 and 623 may be pinned layers having a pinned magnetization direction. In example embodiments, the second magnetic layer 613 may include a structure in which a first pinned layer 613a, a separation layer 613b and a second pinned layer 613c are stacked. The second magnetic layer 623 may include a structure in which a first pinned layer 623a, a separation layer 623b and a second pinned layer 623c are stacked. The first pinned layers 613a and 623a, the separation layers 613b and 623b and the second pinned layers 613c and 623c may be configured substantially in a similar way as the first pinned layer 113a, the separation layer 113b and the second pinned layer 113c included in the oscillation device 11 of FIG. 1, and thus a detailed description thereof will be omitted here.

The driving transistor 63 may be an NMOS transistor having a drain D connected to the first and second oscillation devices 61 and 62, a gate G to which a control signal CON for controlling driving of the first and second oscillation devices 61 and 62 is applied, and a source S connected to a ground terminal. When the control signal CON is activated, the driving transistor 63 may be turned on, and thus output voltages of the first and second oscillation devices 61 and 62 may be provided to the amplifier 64. In example embodiments, the drain D of the driving transistor 63 may be connected to an output node N of the first and second oscillation devices 61 and 62 (i.e., to the second magnetic layers 613 and 623).

The amplifier 64 is connected to the output node N of the first and second oscillation devices 61 and 62 so as to amplify the output voltages of the second first and second oscillation devices 61 and 62 to a set level to provide an output voltage OUT.

In example embodiments, the output node N of the first and second oscillation devices 61 and 62 may be connected to the drain D of the driving transistor 63. Thus, although resistances of the first and second oscillation devices 61 and 62 are changed according to time, currents flowing to the output node N of the first and second oscillation devices 61 and 62 may be maintained at a set level, and a voltage of the output node N may be considerably changed. Accordingly, output power of the oscillator 60 may be considerably increased.

Although not shown in FIG. 25, the oscillator 60 may include at least three oscillation devices connected to one another in series and in parallel.

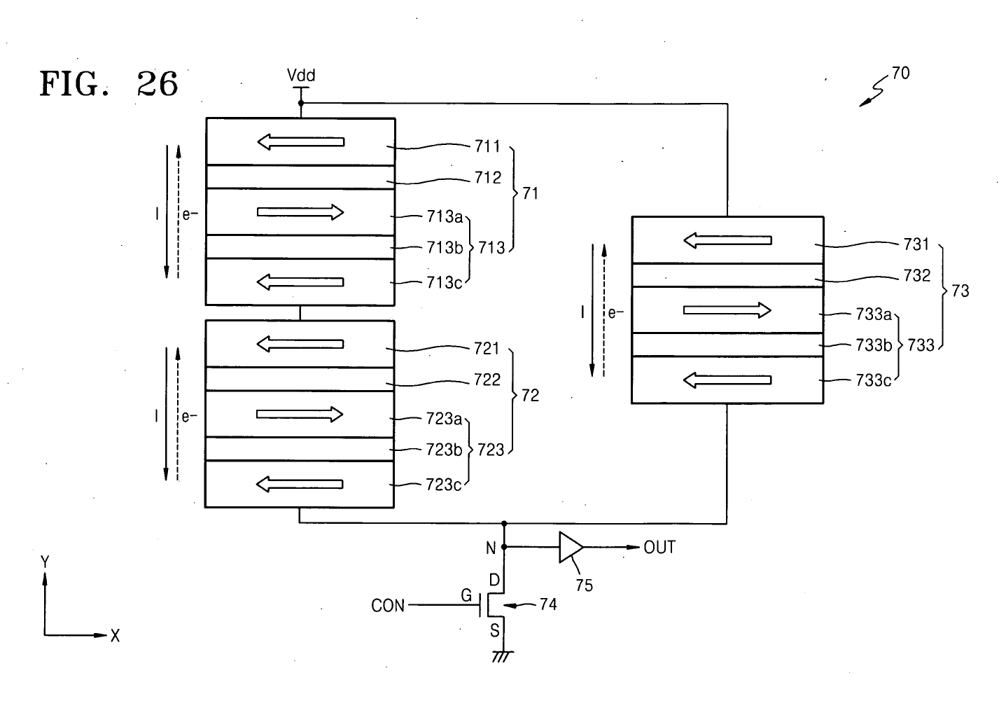

FIG. 26 is a circuit diagram illustrating an oscillator including a plurality of oscillation devices connected to one another in series and in parallel according to example embodiments.

Referring to FIG. 26, an oscillator 70 may include first, second and third oscillation devices 71, 72 and 73 connected to one another in series and in parallel, and driving transistor 74. The oscillator 70 may further include an amplifier 75.

The first oscillation device 71 may include a first magnetic layer 711, a non-magnetic layer 712 and a second magnetic layer 713. The second oscillation device 72 may include a first magnetic layer 721, a non-magnetic layer 722 and a second magnetic layer 723. The third oscillation device 73 may include a first magnetic layer 731, a non-magnetic layer 732 and a second magnetic layer 733. The first magnetic layer 711 of the first oscillation device 71 may be disposed above the second magnetic layer 713, the first magnetic layer 721 of the second oscillation device 72 may be disposed above the second magnetic layer 723, and the first magnetic layer 731 of the third oscillation device 73 may be disposed above the second magnetic layer 733. However, example embodiments are not limited thereto, and thus positions of the second magnetic layers 713, 723 and 733 and positions of the first magnetic layers 711, 721 and 731 may be changed. Meanwhile the configurations of the first, second and third oscillation devices 71, 72 and 73 are not limited thereto, and may be changed as illustrated in FIG. 2.

The first magnetic layers 711, 721 and 731 may be free layers having magnetization directions that are variable according to at least one selected from the group consisting of an applied current, an applied voltage and an applied magnetic field. The first magnetic layers 711, 721 and 731 may be configured substantially in a similar way as the first magnetic layer 111 included in the oscillation device 11 of FIG. 1, and thus a detailed description thereof will be omitted here.

The non-magnetic layer 712 may be disposed between the first magnetic layer 711 and the second magnetic layer 713, the non-magnetic layer 722 may be disposed between the first magnetic layer 721 and the second magnetic layer 723, and the non-magnetic layer 732 may be disposed between the first magnetic layer 731 and the second magnetic layer 733. The non-magnetic layers 712, 722 and 732 may be configured as conductive layers or insulating layers. The non-magnetic layers 712, 722 and 732 may be configured substantially in a similar way as the non-magnetic layer 112 included in the oscillation device 11 of FIG. 1, and thus a detailed description thereof will be omitted here.

The second magnetic layers 713, 723 and 733 may be pinned layers having a pinned magnetization direction. In example embodiments, the second magnetic layer 713 may include a structure in which a first pinned layer 713a, a separation layer 713b and a second pinned layer 713c are stacked. The second magnetic layer 723 may include a structure in which a first pinned layer 723a, a separation layer 723b and a second pinned layer 723c are stacked. The second magnetic layer 733 may include a structure in which a first pinned layer 733a, a separation layer 733b and a second pinned layer 733c are stacked. The first pinned layers 713a, 723a and 733a, the separation layers 713b, 723b and 733b and the second pinned layers 713c, 723c and 733c may be configured substantially in a similar way as the first pinned layer 113a, the separation layer 113b and the second pinned layer 113c included in the oscillation device 11 of FIG. 1, and thus a detailed description thereof will be omitted here.

The driving transistor 74 may be an NMOS transistor having a drain D connected to the second oscillation device 72, a gate G to which a control signal CON for controlling driving of the first, second and third oscillation devices 71, 72 and 73 is applied, and a source S connected to a ground terminal. When the control signal CON is activated, the driving transistor 74 may be turned on, and thus output voltages of the first, second and third oscillation devices 71, 72 and 73 may be provided to the amplifier 75. In example embodiments, the drain D of the driving transistor 74 may be connected to an output node N of the second and third oscillation devices 72 and 73 (i.e., to the second magnetic layers 723 and 733).

The amplifier 75 is connected to the output node N of the second and third oscillation devices 72 and 73 so as to amplify the output voltage of the second and third oscillation devices 72 and 73 to a set level to provide an output voltage OUT.

In example embodiments, the output node N of the second and third oscillation devices 72 and 73 may be connected to the drain D of the driving transistor 74. Thus, although a resistance of the second and third oscillation devices 72 and 73 are changed according to time, a current flowing to the output node N of the second and third oscillation devices 72 and 73 may be maintained to a set level, and a voltage of the output node N may be considerably changed. Accordingly, output power of the oscillator 70 may be considerably increased.

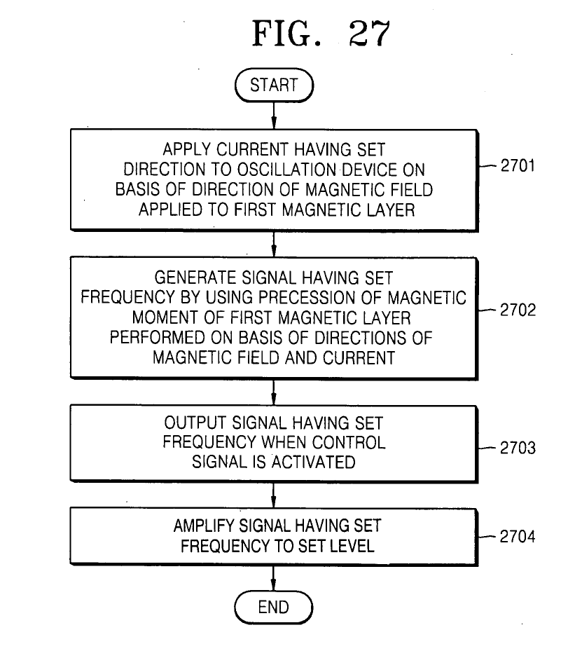

FIG. 27 is a flowchart illustrating a method of operating an oscillator according to example embodiments.

Referring to FIG. 27, the method of operating the oscillator according to example embodiments is the same as methods of operating the oscillators of FIGS. 1 through 26. Accordingly, the descriptions with respect to FIGS. 1 through 26 may be applied to the method of operating the oscillator as shown in FIG. 27.

A current in a set direction is applied to an oscillation device according to a direction of a magnetic field applied to a first magnetic layer (2701).

A signal having a set frequency is generated by using a precession of a magnetic moment of the first magnetic layer that occurs according to the directions of a magnetic field and current (2702).

When a control signal is activated, a signal having a set frequency is output (2703).

The signal having a set frequency is amplified to a set level (2704).

According to example embodiments, an output node of an oscillation device included in an oscillator is connected to a drain of a driving transistor, and thus although a resistance of the oscillation device is periodically changed according to time, a current flowing to the drain of the driving transistor may be maintained at a set level. Thus, a drain voltage of the driving transistor may be considerably changed. Accordingly, because output power of the oscillator is proportional to a square of a voltage of the output node of the oscillator device, the output power of the oscillator may be considerably increased. Thus, even when the oscillator according to example embodiments is manufactured small, a high output voltage may be obtained. In addition, the oscillator may have variable frequency.

It should be understood that the example embodiments described therein should be considered in a descriptive sense only, and not for purposes of limitation. Descriptions of features or aspects within each embodiment should typically be considered as available for other similar features or aspects in other embodiments.

What is claimed is:

1. An oscillator, comprising:
at least one oscillation device including,
a first magnetic layer having a variable magnetization direction,
a second magnetic layer having a pinned magnetization direction, and
a non-magnetic layer disposed between the first magnetic layer and the second magnetic layer, the at least one oscillation device being configured to generate a signal having a set frequency;
a driving transistor having a drain connected to the at least one oscillation device; and
a gate to which a control signal for controlling driving of the oscillation device is applied.

2. The oscillator of claim 1, wherein the magnetization direction of the first magnetic layer varies according to at least one selected from the group consisting of an applied current, an applied voltage and an applied magnetic field,
a magnetic moment of the first magnetic layer precesses according to the at least one selected from the group consisting of an applied current, an applied voltage, and an applied magnetic field, and
a resistance of the oscillation device is periodically changed such that the oscillation device generates the signal having the set frequency.

3. The oscillator of claim 1, wherein the drain is connected to an output node of the oscillation device, and the output node is the first magnetic layer or the second magnetic layer.

4. The oscillator of claim 3, wherein, when a resistance of the oscillation device is periodically changed according to time, a current flowing to the output node is fixed, and a voltage of the output node oscillates at a set amplitude.

5. The oscillator of claim 4, wherein an amplitude of the voltage of the output node is greater than that of a voltage of the output node when the output node is connected to a source of the driving transistor.

6. The oscillator of claim 1, wherein the second magnetic layer includes,
a first pinned layer adjacent to the non-magnetic layer and having a first magnetization direction,
a separation layer adjacent to the first pinned layer, and
a second pinned layer adjacent to the separation layer and having a second magnetization direction opposite to the first magnetization direction.

7. The oscillator of claim 1, wherein the second magnetic layer includes,
a pinned layer adjacent to the non-magnetic layer, and
an anti-ferromagnetic layer adjacent to the pinned layer,
wherein a magnetization direction of the pinned layer is pinned in a direction corresponding to a magnetic moment of an uppermost portion of the anti-ferromagnetic layer.

8. The oscillator of claim 1, further comprising at least two oscillation devices connected to each other in series.

9. The oscillator of claim 1, further comprising at least two oscillation devices connected to each other in parallel.

10. The oscillator of claim 1, further comprising at least three oscillation devices connected to one another in series and in parallel.

11. The oscillator of claim 1, wherein the first magnetic layer is disposed over the non-magnetic layer and the second magnetic layer.

12. The oscillator of claim 1, wherein the second magnetic layer is disposed over the non-magnetic layer and the first magnetic layer.

13. The oscillator of claim 1, wherein, when a magnetic field having a direction opposite to the pinned magnetization direction of the second magnetic layer is applied to the first magnetic layer, a current is applied in a direction from the first magnetic layer to the second magnetic layer.

14. The oscillator of claim 1, wherein, when a magnetic field having a direction that is the same as the pinned magnetization direction of the second magnetic layer is applied to the first magnetic layer, a current is applied in a direction from the second magnetic layer to the first magnetic layer.

15. The oscillator of claim 1, further comprising an amplifier connected to the output node and configured to amplify a voltage of the output node.

16. The oscillator of claim 1, wherein the non-magnetic layer is an insulating layer, and the oscillation device has a tunneling magnetoresistance (TMR) structure.

17. The oscillator of claim 1, wherein the non-magnetic layer is a conductive layer, and the oscillation device has a giant magnetoresistance (GMR) structure.

18. A method of operating an oscillator including an oscillation device having a first magnetic layer, a second magnetic layer and a non-magnetic layer disposed between the first magnetic layer and the second magnetic layer, and a driving transistor having a drain connected to the oscillation device, the method comprising:
applying a current having a set direction to the oscillation device based on a direction of a magnetic field applied to the first magnetic layer; and
generating a signal having a set frequency by using a precession of a magnetic moment of the first magnetic layer that occurs based on the direction of the magnetic field and the set direction of the current.

19. The method of claim 18, further comprising outputting the signal having the set frequency when a control signal is activated, wherein the driving transistor further includes a gate to which the control signal for controlling driving of the oscillation device is applied.

20. The method of claim 19, further comprising amplifying the signal having the set frequency to a set level.
